(19) United States
(12) Patent Application Publication
(10) Pub. No.: US 2025/0334756 A1
(43) Pub. Date: Oct. 30, 2025

(54) PHOTONIC SEMICONDUCTOR PACKAGE AND METHOD OF FORMING THE SAME

(71) Applicant: Taiwan Semiconductor Manufacturing Co., Ltd., Hsinchu (TW)

(72) Inventors: Tung-Liang Shao, Hsinchu (TW); Yu-Sheng Huang, Hemei Township (TW); Chen-Hua Yu, Hsinchu (TW)

(21) Appl. No.: 19/256,352

(22) Filed: Jul. 1, 2025

Related U.S. Application Data
(63) Continuation of application No. 18/415,784, filed on Jan. 18, 2024.
(60) Provisional application No. 63/589,364, filed on Oct. 11, 2023.

(51) Int. Cl. G02B 6/42

(52) U.S. Cl. CPC G02B 6/4214; G02B 6/4244; G02B 6/4245

(57) ABSTRACT

A package includes an interposer, wherein the interposer includes a first waveguide and a first reflector that is optically coupled to the first waveguide; and an optical package attached to the interposer, wherein the optical package includes a second waveguide; and a second reflector that is optically coupled to the second waveguide, wherein the second reflector is vertically aligned with the first reflector.

### PRIORITY CLAIM AND CROSS-REFERENCE

This application is a continuation of U.S. patent application Ser. No. 18/415,784, filed on Jan. 18, 2024, which claims the benefits of U.S. Provisional Application No. 63/589,364, filed on Oct. 11, 2023, which applications are hereby incorporated herein by reference in their entirety.

### BACKGROUND

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) components and electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-9 illustrate intermediate steps in the formation of an optical package, in accordance with some embodiments.

FIG. 10 illustrates a composite interposer, in accordance with some embodiments.

FIGS. 11 and 12 illustrate intermediate steps in the formation of an optical system, in accordance with some embodiments.

FIG. 13 illustrates a magnified view of an optical system, in accordance with some embodiments.

FIG. 14 illustrates a cross-sectional view of a photonic structure, in accordance with some embodiments.

FIG. 15 illustrates a plan view of a photonic structure, in accordance with some embodiments.

FIG. 16 illustrates a cross-sectional view of a photonic structure, in accordance with some embodiments.

FIG. 17 illustrates a magnified view of an optical system, in accordance with some embodiments.

FIG. 18 illustrates a magnified view of an optical system, in accordance with some embodiments.

FIG. 19 illustrates a cross-sectional view of a photonic structure, in accordance with some embodiments.

FIG. 20 illustrates a magnified view of an optical system, in accordance with some embodiments.

FIG. 21 illustrates a magnified view of an optical system, in accordance with some embodiments.

FIG. 22 illustrates a cross-sectional view of a photonic structure, in accordance with some embodiments.

FIG. 23 illustrates a bridge structure, in accordance with some embodiments.

FIG. 24 illustrates an optical package, in accordance with some embodiments.

FIG. 25 illustrates a cross-sectional view of a photonic structure, in accordance with some embodiments.

FIG. 26 illustrates a magnified view of an optical system, in accordance with some embodiments.

FIG. 27 illustrates a plan view of a photonic structure, in accordance with some embodiments.

FIG. 28 illustrates a cross-sectional view of a photonic structure, in accordance with some embodiments.

FIG. 29 illustrates a magnified view of an optical system, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Additionally, arrows are used throughout the figures to indicate the paths of light (e.g., optical signals and/or optical power). It should be understood that for clarity the transmission of light is described along a path in one direction as indicated by arrows, but in some cases light may also be transmitted in the reverse direction along the path.

Various optical structures such interposers, packages, and systems and their methods of formation are described herein. The optical structures may have reflectors formed within that may be configured to receive light from photonic components of the structure and transmit the light vertically where it may be received by another optical structure. Further, the reflectors of a structure may be configured to receive vertically transmitted light and transmit it into photonic components of the structure. In this manner, reflectors may be utilized to transmit optical signals between overlying optical structures. Additionally, lenses may be formed between the overlying optical structures that allow for improved vertical transmission of the optical signals between the optical structures and larger vertical distances between the optical structures.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

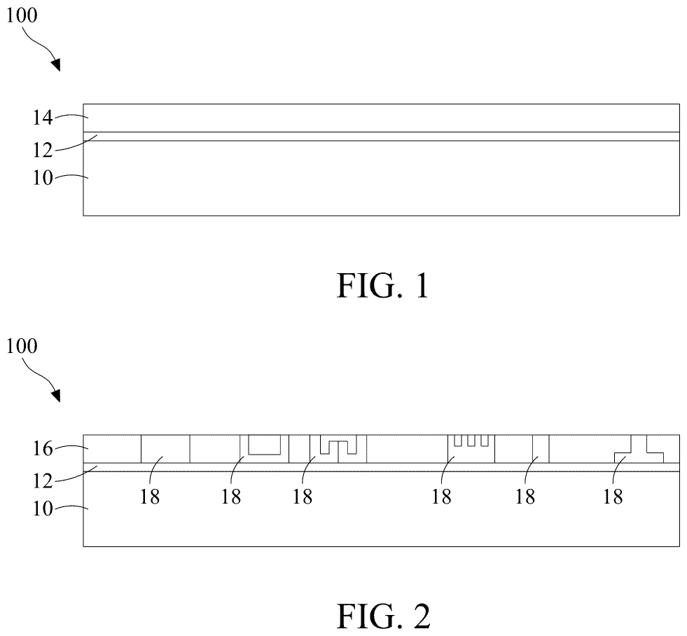

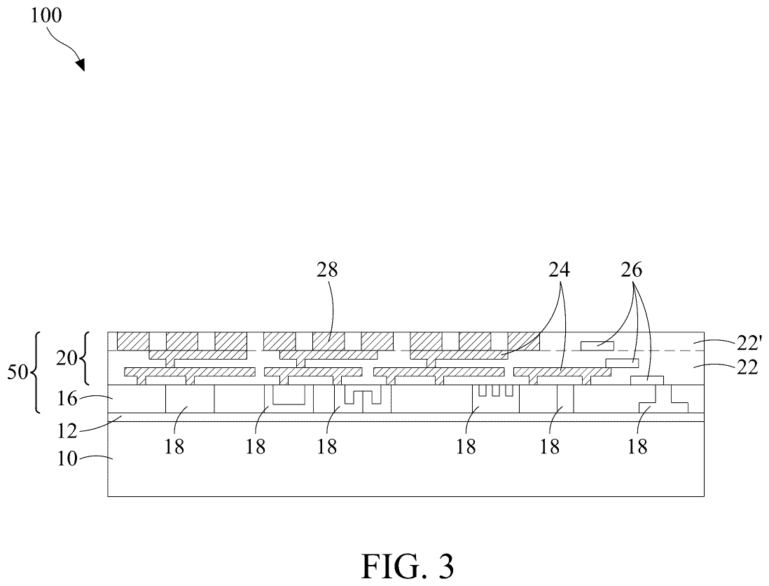

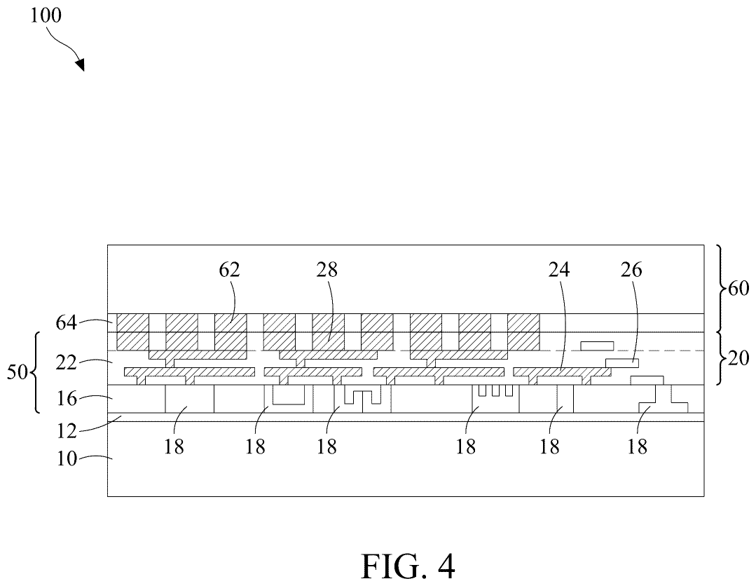

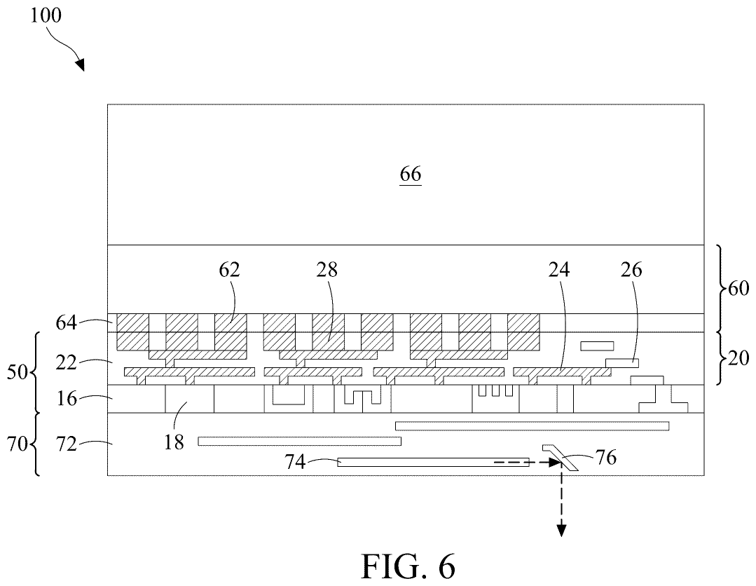

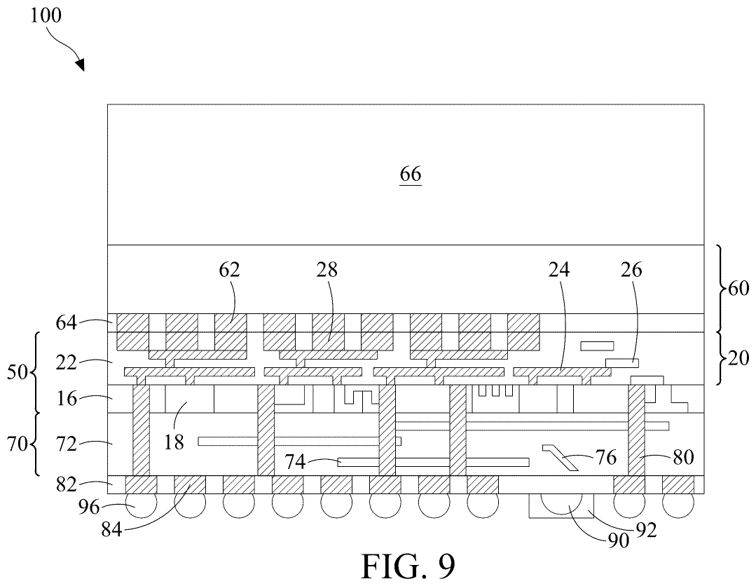

FIGS. 1 through 9 illustrate intermediate steps in the formation of an optical package 100 (see FIG. 9), in accordance with some embodiments. The optical package 100 comprises an optical interposer 50 (see FIG. 3), an optical interconnect structure 70 (see FIG. 6), and an electronic die 60 (see FIG. 4). The optical interconnect structure 70 comprises photonic components 74 and reflectors 76 that allow for the vertical transmission or reception of optical signals, described in greater detail below. The optical package 100 may be configured to receive, generate, modify, transmit, and/or process optical signals. In this manner, the optical package 100 may provide an interface for electrical communication and optical communication in a photonic system. In some cases, the optical package 100 may be considered an “optical engine”, an “optical die,” an “optical structure,” or the like.

FIGS. 1 through 3 illustrate intermediate steps in the formation of an optical interposer 50 (see FIG. 3), in accordance with some embodiments. The optical interposer 50 comprises an interconnect structure 20 (see FIG. 3) formed over photonic components 18 (see FIG. 2), in some embodiments. In some cases, the optical interposer 50 may be considered a photonic integrated circuit (PIC), an optical interconnect structure, or the like. In the particular embodiment illustrated in FIG. 1, the optical interposer 50 comprises at this stage a first substrate 10, a first insulator layer 12, and photonic layer 14. In an embodiment, at a beginning of the manufacturing process of the optical interposer 50, the first substrate 10, the first insulator layer 12, and the photonic layer 14 may collectively be part of a silicon-on-insulator (SOI) substrate or the like, which may be doped (e.g., with a p-type or an n-type dopant) or undoped. The first substrate 10 may be a wafer, such as a silicon wafer. Other substrates, such as a silicon-on-insulator (SOI) substrate, a multi-layered substrate, or a gradient substrate may also be used. In some embodiments, the semiconductor material of the first substrate 10 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In other embodiments, the first substrate 10 may be a dielectric material such as silicon oxide, glass, ceramic, plastic, or any other suitable material that allows for structural support of overlying devices. In some embodiments, multiple optical packages 100 may be formed on the same first substrate 10 and then subsequently separated into individual first optical packages 100 using a singulation process (e.g., a sawing process, dicing process, or the like).

The first insulator layer 12 may be a dielectric layer that separates the first substrate 10 from the overlying photonic layer 14 and can additionally, in some embodiments, serve as a portion of cladding material that surrounds the subsequently manufactured photonic components 18 (described below). In an embodiment, the first insulator layer 12 may be silicon oxide, silicon nitride, germanium oxide, germanium nitride, combinations of these, or the like. The first insulator layer 12 may be formed using a technique such as implantation (e.g., to form a buried oxide (BOX) layer) or using a suitable deposition technique such as chemical vapor deposition (CVD), atomic layer deposition (ALD), physical vapor deposition (PVD), combinations of these, or the like. However, any suitable material and method of manufacture may be used.

In some embodiments, the photonic layer 14 may be a semiconductor material such as silicon, germanium, silicon germanium, combinations of these, or the like. In other embodiments, the photonic layer 14 may comprise a dielectric material such as silicon nitride or the like, a III-V semiconductor material, lithium niobate materials, polymers, the like, or combinations thereof. The photonic layer 14 may be formed using a suitable technique, such as epitaxial growth, CVD, ALD, PVD, the like, or combinations thereof. Other materials or techniques are possible.

FIG. 2 illustrates the formation of photonic components 18 from the photonic layer 14, in accordance with some embodiments. In some embodiments, the photonic components 18 may include such devices or components as optical waveguides (e.g., ridge waveguides, rib waveguides, buried channel waveguides, diffused waveguides, etc.), couplers (e.g., grating couplers, edge couplers comprising a tip waveguide having a width in the range of about 1 nm to about 200 nm, etc.), directional couplers, optical modulators (e.g., germanium modulators, Mach-Zehnder silicon-photonic switches, microelectromechanical switches, micro-ring resonators, etc.), amplifiers, multiplexors, demultiplexors, optical-to-electrical converters (e.g., photodetectors, P-N junctions, or the like), electrical-to-optical converters, lasers (e.g., laser diodes), phase shifters, combinations of these, or the like. However, the photonic components 18 may comprise other devices or components than these examples.

In some embodiments, the photonic components 18 may be formed by patterning the photonic layer 14 into the appropriate shapes for the photonic components 18. In some embodiments, photonic layer 14 may be patterned using one or more photolithographic masking and etching processes, though any suitable method of patterning the photonic layer 14 may be utilized. The patterning may expose portions of the first insulator layer 12. In some cases, additional processing steps may be performed to form some types of photonic components 18, such as additional implantation processes, deposition processes, and/or patterning processes. In some embodiments, one or more photonic components 18 may be formed by patterning the photonic layer 14 and then depositing another material on portions of the patterned photonic layer 14. For example, the formation of a photonic components 18 may comprise patterning a photonic layer 14 comprising silicon and then epitaxially growing a region of germanium on the patterned photonic layer 14, though other materials or process steps are possible.

Sill referring to FIG. 2, a second insulator layer 16 may be formed over the first insulator layer 12 and/or the photonic components 18, in accordance with some embodiments. The second insulator layer 16 may be, for example, a dielectric layer that separates the individual photonic components 18 from each other and from the overlying structures. Further, in some cases, the second insulator layer 16 can additionally serve as a cladding material that at least partially surrounds one or more photonic components 18. In some embodiments, the second insulator layer 16 may comprise silicon oxide, silicon nitride, germanium oxide, germanium nitride, combinations of these, or the like, which may be formed using suitable deposition techniques such as CVD, ALD, PVD, or the like. Other materials or deposition techniques are possible. In some embodiments, after depositing the second insulator layer 16, a planarization process (e.g., a chemical mechanical polishing (CMP) process, a grinding process, or the like) may be performed to planarize a top surface of the second insulator layer 16. In some embodiments, the planarization process may expose a top surface of one or more photonic components 18. In such embodiments, the top surfaces of the photonic components 18 and the top surfaces of the second insulator layer 16 may be level or coplanar (within process variations). In some embodiments, one or more photonic components 18 remain covered by the second insulator layer 16 after performing the planarization process.

FIG. 3 illustrates the formation of an interconnect structure 20 over the photonic components 18, in accordance with some embodiments. The interconnect structure 20 includes dielectric layers 22 (not individually illustrated) and conductive features 24 formed in the dielectric layers 22. The conductive features 24 may comprise conductive lines, conductive vias, conductive pads, metallization patterns, redistribution layers, or the like that provide electrical interconnections and electrical routing within the optical interposer 50. The conductive features 24 may be electrically connected to one or more photonic components 18, in some cases. The interconnect structure 20 may also comprise bond pads 28 at a top surface of the interconnect structure 20, in some embodiments. The bond pads 28 are electrically connected to the conductive features 24 and allow electrical connections to be made to an overlying electronic die 60 or the like, described in greater detail below for FIG. 4.

In some embodiments, the interconnect structure 20 is formed of alternating layers of dielectric material (e.g., dielectric layers 22) and conductive material (e.g., conductive features 24). The conductive features 24 may be formed using any suitable processes such as deposition, damascene, dual damascene, or the like. In particular embodiments, the interconnect structure 20 may have multiple layers of conductive features 24, but the precise number of layers of conductive features 24 may be dependent upon the design of the optical interposer 50. The dielectric layers 22 may be, for example, insulating layers and/or passivating layers, and may comprise silicon oxide, silicon nitride, a polymer, the like, or a combination thereof. The conductive features 24 may include, for example, a metal or a metal alloy such as copper, silver, gold, tungsten, cobalt, ruthenium, aluminum, alloys thereof, combinations thereof, or the like. Other materials are possible.

In some embodiments, the bond pads 28 are formed in the topmost dielectric layer 22′ of the dielectric layers 22. In some embodiments, the bond pads 28 may include via portions (not illustrated) that physically and electrically contact underlying conductive features 24. In some embodiments, the topmost dielectric layer 22′ may be a material suitable for dielectric-to-dielectric bonding, such as silicon oxide, silicon nitride, silicon oxynitride, or the like, and as such the topmost dielectric layer 22′ may be referred to herein as the bonding layer 22′. Other materials are possible. In some embodiments, the bond pads 28 may be formed by first forming openings (not separately illustrated) in the topmost dielectric layer 22′ to expose conductive portions of underlying conductive features 24. The openings may be formed using suitable photolithography and etching techniques. A seed layer is deposited in the openings, and a conductive material is then deposited on the seed layer, in some embodiments. In some embodiments, a liner (not shown), such as a diffusion barrier layer, an adhesion layer, or the like, may be deposited in the openings prior to deposition of the conductive material. The liner may comprise, for example, tantalum nitride, tantalum, titanium nitride, titanium, cobalt tungsten, or the like, and may be formed using a suitable deposition process such as CVD, PVD, ALD, or the like. In some embodiments, the bond pads 28 may be formed by depositing a seed layer (not shown) in the openings. The seed layer may be deposited on the liner, if present. The seed layer may comprise copper, a copper alloy, or the like, in some embodiments. The conductive material may then be formed in the openings using, for example, an electroplating process or an electro-less plating process. The conductive material may be similar to those described for the conductive features 24. For example, the conductive material may be copper or a copper alloy, in some embodiments. A planarization process (e.g., a CMP process or a grinding process) may be performed to remove excess conductive material such that top surfaces of the bond pads 28 and the topmost dielectric layer 22′ are approximately level. This is an example, and the bond pads 28 may be formed using another suitable process.

Additionally, during the manufacture of the interconnect structure 20, one or more photonic components 26 may be formed within the dielectric layers 22. The photonic components 26 may be similar to the photonic components 18 described previously. For example, in some embodiments, the photonic components 26 may include waveguides (e.g., silicon nitride waveguides), couplers, or the like. In some cases, one or more photonic components 26 may be optically coupled to each other and/or to one or more photonic components 18. In this manner, the optical interposer 50 may provide optical communication and optical interconnection within an optical package 100.

In some embodiments, photonic components 26 may be formed during the manufacture of the interconnect structure 20 by depositing a material for photonic components 26 on a dielectric layer 22. The material for the photonic components 26 may be a dielectric material such as silicon nitride, silicon oxide, silicon oxynitride, polymer, combinations of these, or the like, or a semiconductor material such as silicon, germanium, or the like. The material may then be patterned using suitable photolithography and etching techniques. Another dielectric layer 22 may then be deposited on the photonic components 26. In particular embodiments, the interconnect structure 20 may have multiple layers of photonic components 26, but the precise number of layers of photonic components 26 may be dependent upon the design of the optical interposer 50. In this manner, an optical interposer 50 may be formed, in accordance with some embodiments. Other optical interposers 50 having other features or configurations are possible, and other materials or techniques may be used to manufacture an optical interposer 50 in other embodiments.

In FIG. 4, an electronic die 60 is bonded to the interconnect structure 20, in accordance with some embodiments. In some cases, the electronic die may be considered an Electronic Integrated Circuit (EIC) die. FIG. 4 shows a single electronic die 60 bonded to the interconnect structure 20, but in other embodiments more than one electronic die 60 may be bonded to the interconnect structure 20. In some embodiments, the electronic die 60 may include bond pads 62 formed in a bonding layer 64, and the electronic die 60 is bonded to the interconnect structure 20 by dielectric-to-dielectric bonding and/or metal-to-metal bonding (e.g., direct bonding, fusion bonding, oxide-to-oxide bonding, hybrid bonding, or the like), described in greater detail below.

After bonding, the electronic die 60 may be electrically connected to the photonic components 18 and/or the photonic components 26 through the interconnect structure 20. The electronic die 60 may include integrated circuits for interfacing with the photonic components 18/26, such as circuits for controlling the operation of the photonic components 18/26. For example, the electronic die 60 may include controllers, drivers, transimpedance amplifiers, the like, or combinations thereof. The electronic die 60 may include, for example, a chip, a die, a system-on-chip (SoC) device, a system-on-integrated-circuit (SoIC) device, a package, the like, or a combination thereof. The electronic die 60 may include one or more processing devices, such as a central processing unit (CPU or “xPU”), a graphics processing unit (GPU), an application-specific integrated circuit (ASIC), a high performance computing (HPC) die, a logic die, the like, or a combination thereof. The electronic die 60 may include one or more memory devices, which may be a volatile memory such as dynamic random-access memory (DRAM), static random-access memory (SRAM), high-bandwidth memory (HBM), another type of memory, or the like. In some embodiments, the electronic die 60 includes circuits for processing electrical signals received from photonic components 18/26, such as for processing electrical signals received from a photonic component 18/26 comprising a photodetector. The electronic die 60 may control high-frequency signaling of the photonic components 18/26 according to electrical signals (digital or analog) received from another device or die, in some embodiments. In some embodiments, the electronic die 60 may provide Serializer/Deserializer (SerDes) functionality. In some embodiments, the electronic die 60 may act as part of an I/O interface between optical signals and electrical signals within an optical package 100, and the optical package 100 described herein could be considered a system-on-chip (SoC) device or a system-on-integrated-circuit (SoIC) device.

In some embodiments, the bonding layer 64 of the electronic die 60 is bonded to the bonding layer 22′ (e.g., the topmost dielectric layer 22′) of the optical interposer 50 using a dielectric-to-dielectric bonding process, and the bond pads 62 of the electronic die 60 are bonded to corresponding bond pads 28 of the optical interposer 50 using a metal-to-metal bonding process. In some embodiments, the bonding process may be initiated by activating the bonding surfaces of the bonding layer 64 and the bonding layer 22′, which can facilitate bonding of the bonding surfaces. Activating the bonding surfaces may comprise, for example, a dry treatment, a wet treatment, a plasma treatment, exposure to an inert gas plasma, exposure to H₂, exposure to N₂, exposure to O₂, combinations thereof, or the like. For embodiments in which a wet treatment is used, an RCA cleaning process may be used, for example. In other embodiments, the activation process may comprise other types of treatments.

After the activation process, the optical interposer 50 and the electronic die 60 may be cleaned using, e.g., a chemical rinse or the like, and then the electronic die 60 is aligned and placed into physical contact with the optical interposer 50. The optical interposer 50 and the electronic die 60 are then subjected to a thermal treatment and contact pressure to bond the bonding layer 64 to the bonding layer 22′ with dielectric-to-dielectric bonding and bond the bond pads 62 to the bond pads 28 with metal-to-metal bonding. In some embodiments, the bonded structure is subsequently baked, annealed, pressed, or otherwise treated to strengthen or finalize the bond. This is an example, and other bonding processes are possible.

FIG. 4 illustrates an embodiment in which the electronic die 60 has the same width as the optical interposer 50. For example, a singulation process may subsequently be performed that leaves approximately coplanar sidewalls of the electronic die 60 and the optical interposer 50. In other embodiments, the electronic die 60 may have a smaller width than the optical interposer 50. In such embodiments, a gap-fill material may be deposited in order to fill the space around the electronic die 60 and provide additional support. The gap-fill material may be a material such as silicon oxide, silicon nitride, silicon oxynitride, an encapsulant, a molding material, a polymer, combinations of these, or the like, though other materials are possible. In some embodiments, a planarization process (e.g., CMP or grinding) may be performed to remove excess gap-fill material and/or expose the electronic die 60.

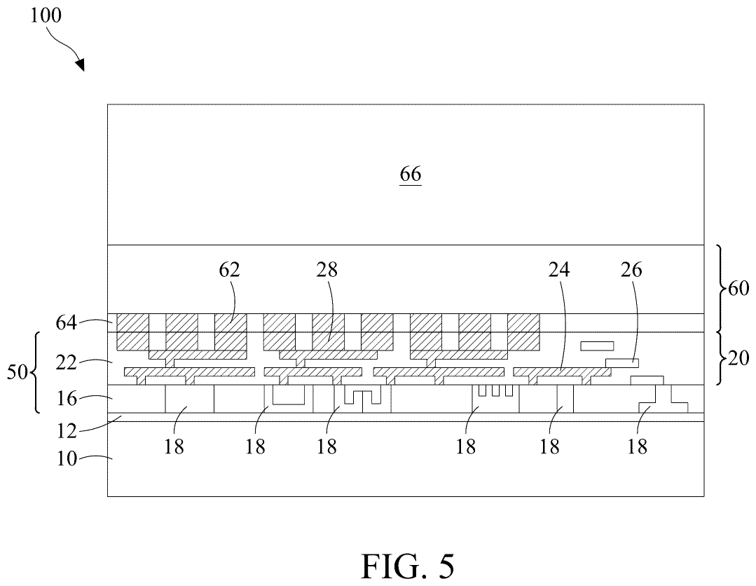

In FIG. 5, a support substrate 66 is attached to the electronic die 60, in accordance with some embodiments. The support substrate 66 is a rigid structure that is attached to provide structural or mechanical stability. The support substrate 66 may comprise one or more materials such as silicon (e.g., a silicon wafer, bulk silicon, or the like), a silicon oxide, a metal, an organic core material, the like, or another type of material. In some embodiments, the support substrate 66 is attached to the electronic die 60 using dielectric-to-dielectric bonding. For example, bonding layers (not separately illustrated) may be formed on the electronic die 60 and on the support substrate 66 and then bonded together. The bonding layers may be similar to the bonding layers 22′ or 64 and may be bonded together using dielectric-to-dielectric bonding techniques similar to those described for FIG. 4. Other materials or bonding techniques are possible. In other embodiments, the support substrate 66 may be attached using an adhesive layer (not separately illustrated) or the like.

In FIG. 6, the first substrate 10 is removed and an optical interconnect structure 70 is formed on the optical interposer 50, in accordance with some embodiments. In some embodiments, the first substrate 10 and the first insulator layer 12 are removed using a planarization process, such as a CMP process, a grinding process, one or more etching processes, combinations of these, or the like. Removing the first insulator layer 12 may expose the second insulator layer 16 and the photonic components 18. In other embodiments, only the first substrate 10 is removed, and the first insulator layer 12 is left remaining.

The optical interconnect structure 70 may comprise photonic components 74 formed within one or more dielectric layers 72 (not individually illustrated), in accordance with some embodiments. The photonic components 74 may be similar to the photonic components 18 or 26 described previously. For example, in some embodiments, the photonic components 74 may include waveguides (e.g., silicon nitride waveguides), couplers, or the like. In some cases, one or more photonic components 74 may be optically coupled to each other and/or to one or more photonic components 18. In this manner, the optical interconnect structure 70 may provide optical communication and optical interconnection within an optical package 100.

The photonic components 74 may be formed using materials or techniques similar to those used to form the photonic components 26, in some embodiments. For example, the photonic components 74 are formed by depositing a material for photonic components 74 on a dielectric layer 72 and then patterning the material using suitable photolithography and etching techniques. The material for the photonic components 74 may be a dielectric material such as silicon nitride, silicon oxide, silicon oxynitride, polymer, combinations of these, or the like, or a semiconductor material such as silicon, germanium, or the like. Another dielectric layer 72 may then be deposited on the photonic components 74. The dielectric layers 72 may comprise, for example, silicon oxide, spin-on glass, or the like, which may include materials transparent or mostly transparent within a relevant range of wavelengths. Other materials are possible. In particular embodiments, the optical interconnect structure 70 may have multiple layers of photonic components 74, but the precise number of layers of photonic components 74 may be dependent upon the design of the optical package 100.

In some embodiments, the optical interconnect structure 70 may include one or more reflectors 76. A reflector 76 is a reflective structure (e.g., a mirror or the like) that may be formed within one or more dielectric layers 72 of the optical interconnect structure 70. A reflector 76 is optically coupled to a photonic component 74 and configured to receive optical signals from the photonic component 74 and redirect those optical signals toward an external photonic component (e.g., of another package, chip, die, interposer, etc.). For example, a reflector 76 may enable the vertical transmission of optical signals. A reflector 76 may additionally or alternatively be configured to receive optical signals from an external photonic component and redirect them toward a photonic component 74 to couple those optical signals into that photonic component 74. For example, a reflector 76 may be formed near a photonic component 74 (e.g., a waveguide) and be configured to receive light from that photonic component 74 and reflect the received light through one or more dielectric layers 72 and out of the optical interconnect structure 70, as indicated by the dashed arrows in FIG. 6. The reflector 76 may also be configured to receive light from outside of the optical interconnect structure 70 and couple it into a nearby photonic component 74. In this manner, optical signals may be communicated between the optical package 100 and other dies, packages, structures, or photonic components. The reflector 76 may be formed of or comprise one or more layers of metallic material such as copper, aluminum, tantalum, AlCu, AlCuSi, the like, alloys thereof, and/or multi-layers thereof. Other materials are possible.

In some embodiments, a reflector 76 may be formed by etching a recess (not separately illustrated) into the dielectric layers 72 and then depositing metallic material on the bottom surface of the recess. In some embodiments, the bottom surface of the recess may be slanted or stepped such that the deposited metallic material forms a similarly slanted or stepped reflective surface. The bottom surface of the recess may be planar, stepped, convex, concave, or curved. The recess may be formed using one or more photolithography and etching steps. In some embodiments, the recess may be formed using “grayscale” photolithography techniques that allow for the formation of a recess having a particular bottom surface profile (e.g., a slanted or curved surface profile). The metallic material may then be deposited in the recess to coat a bottom surface of the recess, forming a reflective layer on the bottom surface of the recess. In some embodiments, undesired metallic material may be removed after deposition using photolithography and etching techniques. In other embodiments, a patterned photoresist layer may be formed before deposition of the metallic material such that removing the photoresist layer also removes undesired metallic material. The remaining metallic material forms the reflector 76. Other processes of forming a reflector 76 are possible.

In some embodiments, after forming the reflector 76, the recess is filled with a dielectric material (not separately illustrated). The dielectric material may comprise a material such as silicon oxide, silicon nitride, polyimide, polybenzoxazoles (PBO), or the like. The dielectric material may be a material similar to that of the dielectric layers 72, in some embodiments. In some embodiments, a planarization process (e.g., CMP or grinding) may be performed to remove excess dielectric material after filling the recess. In some embodiments, surfaces of a dielectric layer 72 and the dielectric material may be level after performing the planarization process.

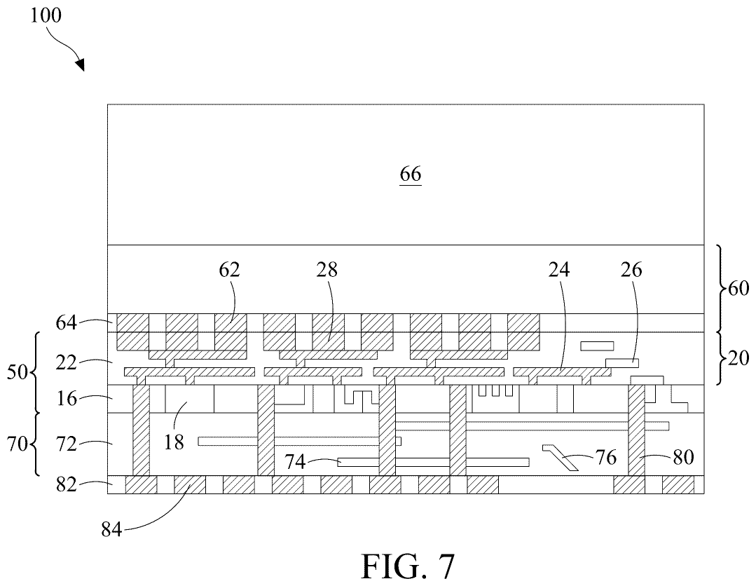

In FIG. 7, vias 80 are formed extending through the optical interconnect structure 70 and the second insulator layer 16, in accordance with some embodiments. The vias 80 may physically and electrically contact conductive features 24 of the interconnect structure 20. In some embodiments, the vias 80 may extend into one or more of the dielectric layers 22. The vias 80 may be formed, for example, by forming openings extending through the dielectric layers 72, the second insulator layer 16, and/or one or more dielectric layers 22 to expose surfaces of the conductive features 24. The openings may be formed using acceptable photolithography and etching techniques, such as by forming and patterning a photoresist and then performing an etching process using the patterned photoresist as an etching mask. The etching process may include, for example, a dry etching process and/or a wet etching process. A conductive material may then be formed in the openings, thereby forming the vias 80. In some embodiments, a liner (not shown) may be deposited in the openings prior to forming the conductive material. The conductive material may comprise, for example, a metal or a metal alloy such as copper, silver, gold, tungsten, cobalt, aluminum, alloys thereof, or the like. A planarization process (e.g., a CMP process or a grinding process) may be performed to remove excess conductive material along the surface of the optical interconnect structure 70 (e.g., the dielectric layers 72), such that surfaces of the vias 80 and the optical interconnect structure 70 are level. Other materials or techniques are possible. In other embodiments, the vias 80 are omitted.

Still referring to FIG. 7, a passivation layer 82 may be formed over the optical interconnect structure 70, in accordance with some embodiments. The passivation layer 82 may comprise, for example, a polymer such as PBO, polyimide, BCB, or the like; a nitride such as silicon nitride or the like; an oxide such as silicon oxide, PSG, BSG, BPSG, or the like; an encapsulant, molding compound, or the like; the like, or a combination thereof. The passivation layer 82 may be formed, for example, by spin coating, lamination, CVD, PVD, ALD, or the like. In some embodiments, photonic components such as waveguides or the like may also be formed in the passivation layer 82.

Under-bump metallizations (UBMs) 84 may then be formed within the passivation layer 82 to make physical and electrical contact to the vias 80. In other embodiments, the UBMs 84 are formed prior to forming the passivation layer 82. In some embodiments, openings are formed in the passivation layer 82 that may expose the UBMs 84. The openings may be formed using acceptable photolithography and etching techniques, such as by forming and patterning a photoresist and then performing an etching process using the patterned photoresist as an etching mask. The etching process may include, for example, a dry etching process and/or a wet etching process. One or more conductive materials may then be deposited in the openings, forming the UBMs 84. In other embodiments, the UBMs 84 have bump portions on and extending along the major surface of the passivation layer 82. In some embodiments, the UBMs 84 are not formed.

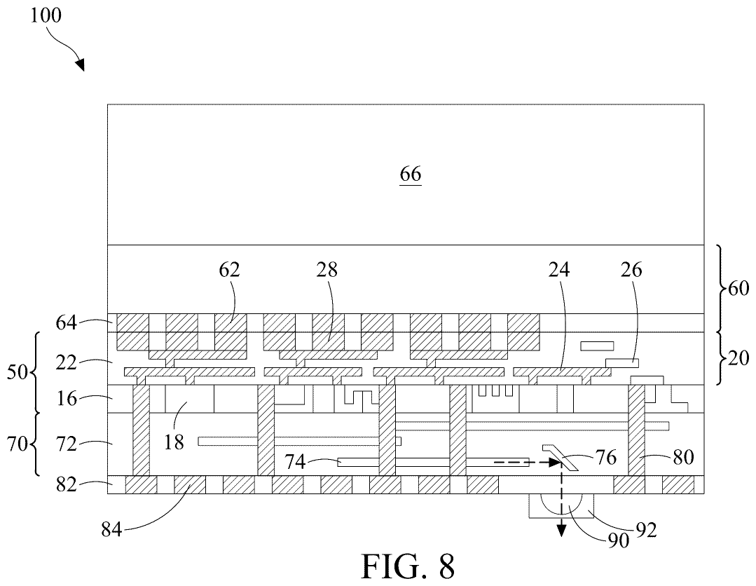

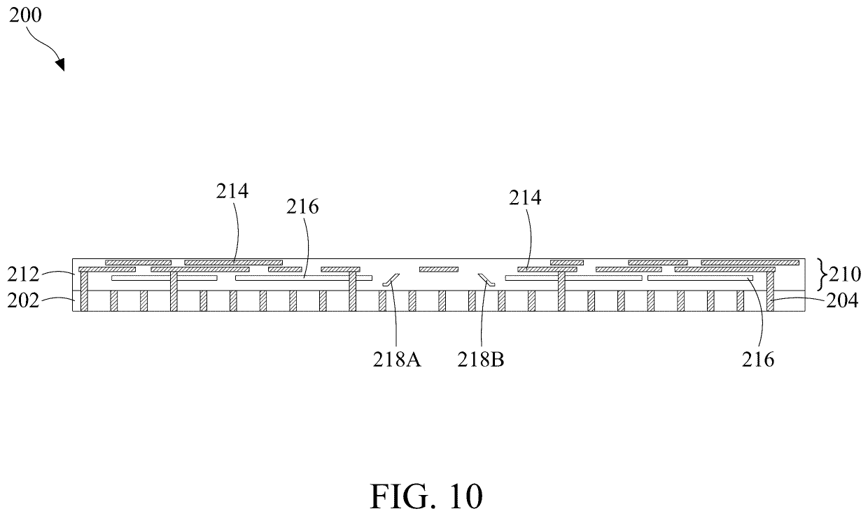

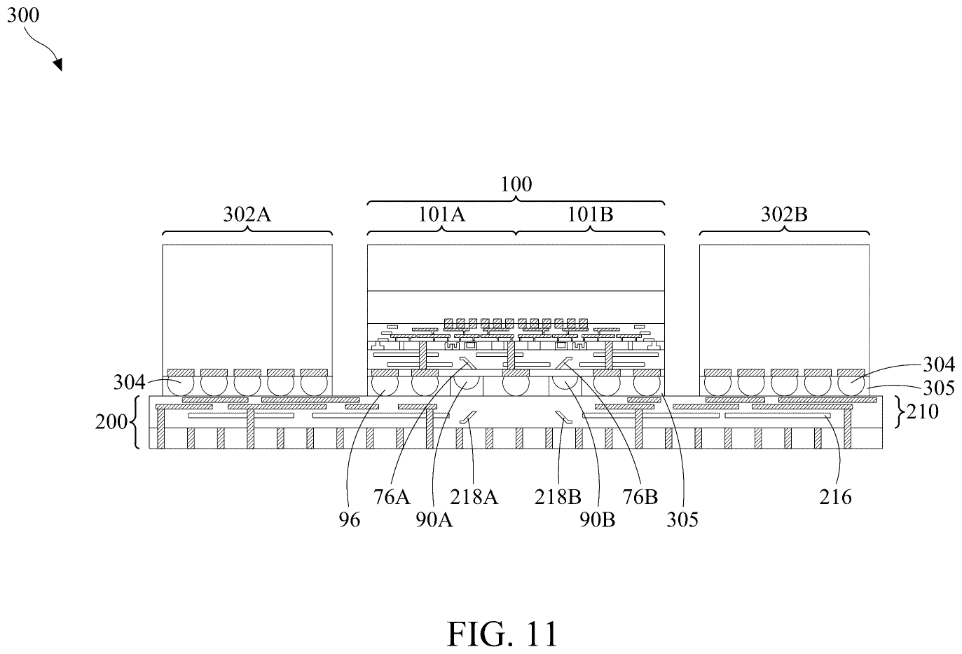

In FIG. 8, a lens 90 is attached to the passivation layer 82, in accordance with some embodiments. The lens 90 may receive light from the reflector 76 and focus or otherwise shape the light such that the light may be more efficiently coupled into an external photonic structure (e.g., a composite interposer 200 (see FIG. 11) or the like). The lens 90 may also receive light from an external photonic structure and focus or otherwise shape the light such that the light received by the reflector 76 is more efficiently coupled into a photonic structure 74. In this manner, the transmission of optical signals between the optical package 100 and an external photonic structure may have improved efficiency. In some cases, the use of the lens 90 may also allow for improved offset tolerance (lateral and/or vertical) for optical communications between the optical package 100 and another photonic component (e.g., composite interposer 200 in FIG. 10). In some embodiments, the lens 90 may be affixed to the passivation layer 82 using an optical glue 92 or the like.

In some embodiments, the lens 90 may be formed using a laser-writing process. A laser-writing process focuses a laser on a localized region within a material, changing the material properties of that localized region. For example, the laser may increase the refractive index of the localized region relative to adjacent (e.g., not laser-written) regions. The laser writing process used to form the lens 90 may be a Femtosecond Direct Laser Writing process or the like, in some embodiments. In some embodiments, the size, shape, location, optical properties, or other properties of a lens 90 may depend on the material(s) of the lens 90 or may be controlled by controlling parameters such as laser wavelength, laser pulse energy, focal spot size, laser intensity profile or phase profile, laser pulse width (e.g., duration), laser pulse repetition rate or duty cycle, laser writing path speed, laser writing direction, laser polarization, or other parameters. Accordingly, the material of the lens 90 may comprise a material that is suitable for a laser-writing, such as a borosilicate glass, a soda-lime-silica glass, a fluoride glass (e.g., fluorozirconate glass or the like), another type of glass, a high-silica (e.g. silicon oxide-based) material, a polymer, or the like. In this manner, a lens 90 may comprise a laser-written material. In some embodiments, the lens 90 may be formed using a laser-writing process and then attached to the passivation layer 82. In other embodiments, the material for the lens 90 may be attached to the passivation layer 82, and then the laser-writing process may be performed to form the lens 90 within the material. Forming a lens 90 using a laser-writing process can allow for design flexibility, improve structural stability, reduced cost, and/or reduced size of a photonic system such as the optical package 100.

In FIG. 9, conductive connectors 96 are formed on the UBMs 84, in accordance with some embodiments. The conductive connectors 96 may be, for example, ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 96 may include a conductive material such as solder, copper, aluminum, gold, nickel, silver, palladium, tin, the like, or a combination thereof. In some embodiments, the conductive connectors 96 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 96 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. In other embodiments, the conductive connectors 96 are omitted and the UBMs 84 are bonding pads used for metal-to-metal bonding to an external component. In some embodiments, a thickness of the lens 90 is less than a thickness of the conductive connectors 96. In this manner, an optical package 100 may be formed, though an optical package 100 may be formed using other materials or process steps in other embodiments.

FIG. 10 illustrates a composite interposer 200, in accordance with some embodiments. The composite interposer 200 comprises a substrate 202, an interconnect structure 210 on the substrate 202, and through vias 204, in accordance with some embodiments. The substrate 202 may be a semiconductor substrate (e.g., a silicon wafer) or another type of substrate, such as those described previously for the first substrate 10.

The interconnect structure 210 comprises one or more layers of conductive features 214 formed in one or more dielectric layers 212 (not individually illustrated). The conductive features 214 may include conductive lines, conductive vias, conductive pads, or the like, which may be formed using any suitable technique such as damascene, dual damascene, or the like. For example, the conductive features 214 may be formed using techniques similar to those described previously for the conductive features 24. Additionally, in some embodiments, the interconnect structure 210 comprises one or more waveguides 216 formed in the dielectric layers 212. The waveguides 216 may be formed of silicon, silicon nitride, or another suitable material, and may be formed using any suitable techniques, such as techniques described previously for the photonic components 18, 26, or 74. In some embodiments, the interconnect structure 210 may have one layer of waveguides 216, as shown in FIG. 10, or may have multiple layers of waveguides 216. Some waveguides 216, including those on different layers, may be optically coupled. The waveguides 216 may be formed within dielectric layer(s) 212 near a top surface of the interconnect structure 210 or may be formed within interior dielectric layer(s) 212. In some embodiments, the waveguides 216 may include other photonic structures, such as grating couplers, evanescent couplers, edge couplers, or other types of structures.

In some embodiments, the interconnect structure 210 may also include reflectors 218 (e.g., reflectors 218A-B) formed within the dielectric layer 212. The reflectors 218 may be similar to the reflectors 76 described previously, and may be formed using similar materials or techniques. In some embodiments, the reflectors 218 may be configured or arranged to couple optical signals between waveguides 216 and overlying photonic components. For example, light may be transmitted through dielectric layers 212 of the interconnect structure 210 to the reflector 218, which reflects the light into an adjacent waveguide 216. In this manner, a reflector 218 may enable the vertical transmission of optical signals. Similarly, light may be transmitted from a waveguide 216 toward an adjacent reflector 218, which redirects the light such that the light is transmitted out of a top surface of the interconnect structure 210. In some embodiments, reflectors 218 may be formed in different layers of the interconnect structure 210. In some embodiments, regions of the interconnect structure 210 above the reflectors 218 (e.g., regions between the reflectors 218 and the top surface of the interconnect structure 210) may be free of conductive features 214 and waveguides 216 in order to provide efficient and unblocked transmission of optical signals through dielectric layers 212.

The through vias 204 of the composite interposer 200 extend through the substrate 202 and are electrically connected to the interconnect structure 210. The through vias 204 may be formed using techniques similar to those described previously for the vias 80. For example, openings may be etched that extend through the substrate 202 and may extend through one or more dielectric layers 212 to expose conductive features 214. The openings may then be filled with conductive material to form the through vias 204.

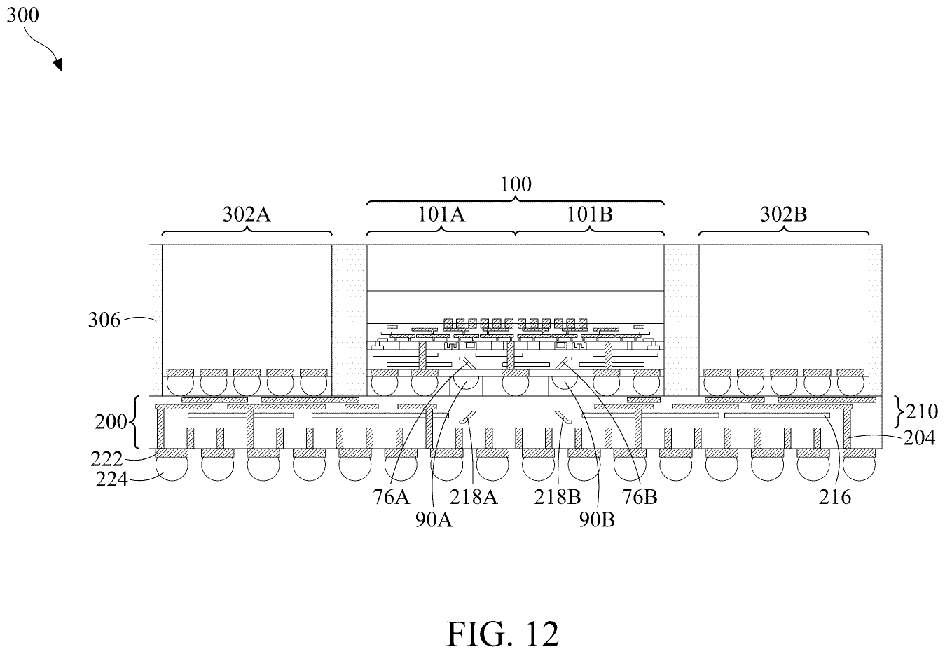

FIGS. 11 and 12 illustrate intermediate steps in the formation of an optical system 300, in accordance with some embodiments. In some embodiments, an optical system 300 comprises a composite interposer 200, one or more optical packages 100, and one or more device dies 302, described in greater detail below. In FIG. 11, an optical package 100 and one or more device dies 302 are connected to the composite interposer 200, in accordance with some embodiments. FIG. 11 illustrates one optical package 100 and two device dies 302A-B, but in other embodiments, any suitable number of optical packages 100 or device dies 302 may be connected to a composite interposer 200 in any suitable arrangement. As described in greater detail below, the optical package 100 and the device dies 302 may be electrically connected to the composite interposer 200, and the optical package 100 may be optically coupled to the composite interposer 200.

Each of the device dies 302 may include, for example, a chip, a die, a system-on-chip (SoC) device, a system-on-integrated-circuit (SoIC) device, a package, the like, or a combination thereof. The device dies 302 may comprise logic dies, memory dies, input-output (I/O) dies, Integrated Passive Devices (IPDs), or the like, or combinations thereof. For example, the device dies 302 may comprise logic dies such as Central Processing Unit (xPU or CPU) dies, Graphic Processing Unit (GPU) dies, mobile application dies, Micro Control Unit (MCU) dies, BaseBand (BB) dies, Application processor (AP) dies, Application-Specific Integrated Circuit (ASIC) dies, or the like. The device dies 302 may comprise memory dies such as Static Random-Access Memory (SRAM) dies, Dynamic Random-Access Memory (DRAM) dies, High-Bandwidth Memory (HBM) dies, or the like. Different device dies 302 (e.g., device dies 302A-B) on the composite interposer 200 may be similar types or different types, and other types of device dies 302 are possible. In some embodiments, conductive connectors 304 are formed on the device dies 302. The conductive connectors 304 may be similar to the conductive connectors 96, in some cases. For example, the conductive connectors 304 may comprise ball grid array (BGA) connectors, solder balls, metal pillars, controlled collapse chip connection (C4) bumps, micro bumps, electroless nickel-electroless palladium-immersion gold technique (ENEPIG) formed bumps, or the like.

The optical package 100 of FIG. 11 may be similar to the optical package 100 described previously for FIG. 9, except that the optical package 100 of FIG. 11 comprises multiple reflectors 76 (e.g., reflectors 76A-B) and multiple lenses 90 (e.g., lenses 90A-B). Further, in some embodiments, the optical package 100 may comprise multiple device regions 101 (e.g., device regions 101A-B). Each device region 101 may be a region of the optical package 100 that is at least partially dedicated to processing particular optical signals. For example, in some embodiments, a device region 101 may have components, features, and/or functionality similar to that of the optical package 100 described for FIG. 9. In some cases, multiple device regions 101 may be formed in a single optical package 100 rather than forming multiple individual optical packages 100. Forming multiple device regions 101 within a single optical package 100 in this manner can reduce processing cost and device size. In some cases, device regions 101 may be associated with certain device dies 302. As an example, in FIG. 11, the device region 101A may process optical signals associated with the device die 302A, and the device region 101B may process optical signals associated with the device die 302B. In some embodiments, a device region 101 may convert optical signals into electrical signals and transmit them to an associated device die 302, or may receive electrical signals from an associated device die 302 and convert them into optical signals. Each device region 101 may comprise one or more reflectors 76 and one or more lenses 90, in accordance with some embodiments. Other configurations or associations are possible. In some embodiments, device regions 101 of the same optical package 100 may communicate with each other using optical signals and/or electrical signals.

In some embodiments, the optical package 100 and the device dies 302 may be connected to the composite interposer 200 by conductive connectors 96 and 304, respectively. For example, the conductive connectors 96 of the optical package 100 and the conductive connectors 304 of the device dies 302 may be placed on corresponding conductive pads (not separately illustrated) of the interconnect structure 210 of the composite interposer 200. Then, a reflow process may be performed to bond the optical package 100 and the device dies 302 to the composite interposer 200. In this manner, the optical package 100 and the device dies 302 may be electrically connected to the composite interposer 200, and the composite interposer 200 may provide electrical connections between optical packages 100 and/or device dies 302. A composite interposer 200 may also provide optical connections between optical packages 100, described in greater detail below. In some embodiments, an underfill 305 may be deposited between the optical package 100 and the composite interposer 200 and between the device dies 302 and the composite interposer 200. The underfill 305 may be formed underneath individual or multiple optical packages 100 and/or device dies 302.

In FIG. 12, the optical package 100 and the device dies 302 are encapsulated by an encapsulant 306, in accordance with some embodiments. The encapsulant 306 may be, for example, a molding material, an epoxy, a polymer, or the like. The encapsulant 306 may surround the optical package 100 and the device dies 302, in some embodiments. In some embodiments, the encapsulant 306 may also be deposited on a top surface of the composite interposer 200, as shown in FIG. 12. In some embodiments, a planarization process (e.g., a CMP process or grinding process) is performed to remove excess encapsulant 306. The planarization process may expose top surfaces of the optical package 100 and the device dies 302. Top surfaces of the encapsulant 306, the optical package 100, and/or the device dies 302 may be approximately level after performing the planarization process.

Still referring to FIG. 12, conductive connectors 224 may be formed on the composite interposer 200, in accordance with some embodiments. UBMs 222 may be formed on the composite interposer 200 that are electrically connected to through vias 204, in some embodiments. The UBMs 222 may be conductive pads or the like, and may be similar to the UBMs 84 described for FIG. 7. The conductive connectors 224 may be solder balls, solder bumps, or the like, and may be similar to the conductive connectors 96 or 304 described previously. The conductive connectors 224 allow for electrical connections to be made between the composite interposer 200 and an external component. In this manner, an optical system 300 may be formed, though other manufacturing steps, arrangements of features, or configurations of features are possible.

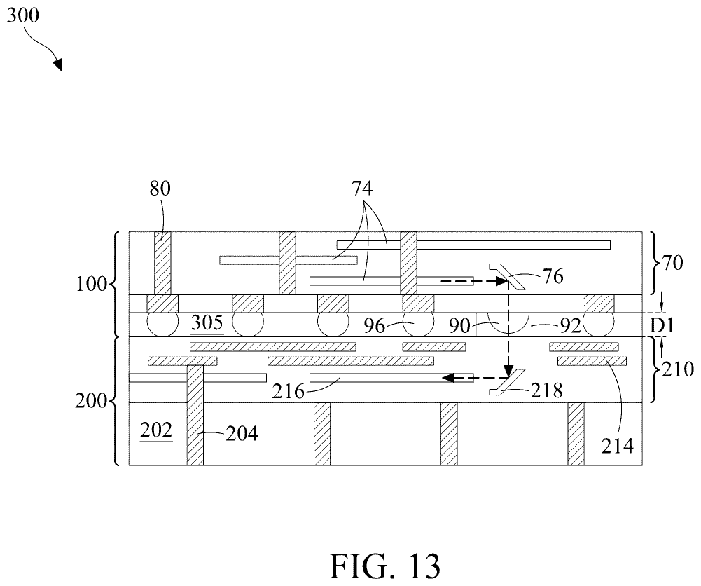

FIG. 13 illustrates a magnified view of a portion of an optical system 300, in accordance with some embodiments. The optical system 300 of FIG. 13 may be similar to the optical system 300 of FIG. 12. The magnified view of FIG. 13 shows portions of an optical package 100 and the composite interposer 200, which may be similar to corresponding features shown in FIG. 12 or elsewhere herein. As shown in FIG. 13, the lens 90 of the optical package 100 is located between a bottom surface of the optical package 100 and a top surface of the composite interposer 200. The optical glue 92 may cover the lens 90 and may extend between a bottom surface of the optical package 100 and a top surface of the composite interposer 200. The underfill 305 may surround the lens 90, as shown in FIG. 13. In some embodiments, a bottom surface of the optical package 100 and a top surface of the composite interposer 200 may be separated by a distance D1. In some cases, the distance D1 is about the same as the combined thickness of the lens 90 and the optical glue 92. The thickness of the lens 90 is less than or about the same as a thickness of the conductive connectors 96, which is about the same as the distance D1. In this manner, the use of a laser-written lens 90 allows conductive connectors 96 to be used for connection while reducing optical loss from optical signals transmitted between the optical package 100 and the composite interposer 200, described in greater detail below.

The use of a reflector 76 and a lens 90 in the optical package 100 and a reflector 218 in the composite interposer 200 can facilitate efficient transmission of optical signals between the optical package 100 and the composite interposer 200. For example, a reflector 76 may be configured to receive light from a photonic component 74 (e.g., a waveguide or the like) and redirect the received light through the lens 90, as indicated by the dashed arrows in FIG. 13. A corresponding reflector 218 in the composite interposer 200 may be configured to receive light from the lens 90 and redirect the light into a waveguide 216. Similarly, the reflector 218 may receive light from the waveguide 216 and redirect the light through the lens 90 and into the reflector 76, which redirects the light into the photonic component 74. In other embodiments, reflectors 76/218 and the corresponding lens 90 may be configured to transmit light only in one direction (e.g., from the optical package 100 to the composite interposer 200 or vice versa).

In some embodiments, each reflector 76 has a corresponding lens 90 and a corresponding reflector 218. For example, referring to FIG. 12, the reflector 76A may correspond to the lens 90A and the reflector 218A, and the reflector 76B may correspond to the lens 90B and the reflector 218B. In some embodiments, corresponding reflectors 76/218 may be vertically aligned, as shown in FIG. 13. In some cases, corresponding reflectors 76/218 may be considered “optically coupled.” In other embodiments, a lens 90 may be attached to the composite interposer 200 and not to the optical package 100 (not separately illustrated). As described previously, the use of a laser written lens 90 can improve transmission efficiency and improve optical coupling, such as the optical coupling between the reflectors 76 and 218. For example, the use of a laser-written lens 90 as described herein can enable larger vertical light transition offset tolerance between the optical package 100 and the composite interposer 200.

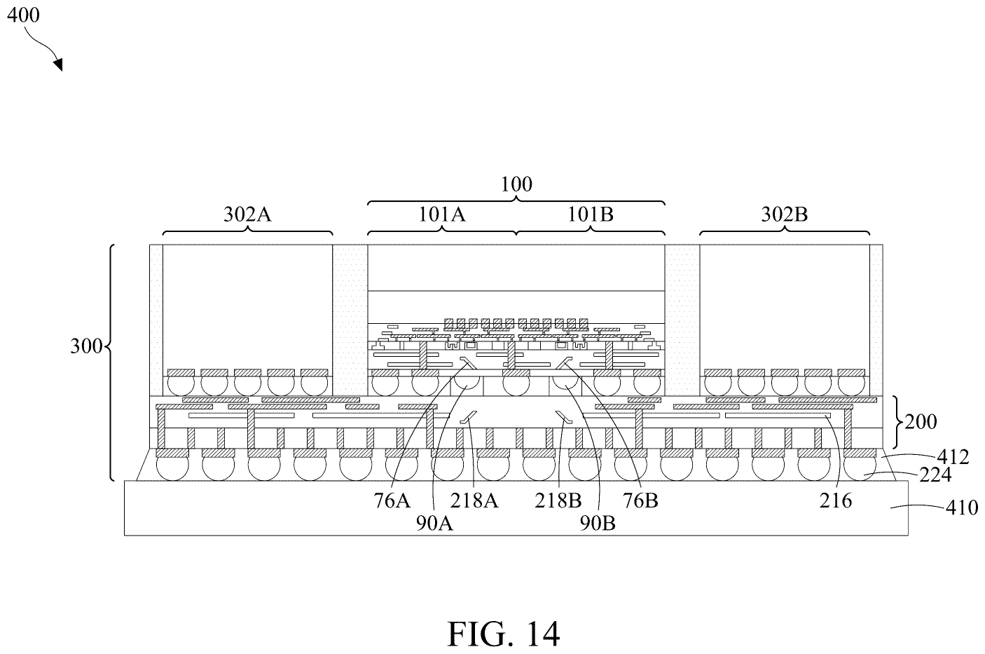

FIG. 14 illustrates an optical system 300 attached to a substrate 410 to form a photonic structure 400, in accordance with some embodiments. Multiple optical systems 300 may be attached to the substrate 410 in other embodiments. The optical system 300 may be similar to the optical system 300 shown in FIG. 12 or may be similar to other optical systems described herein. In some embodiments, the substrate 410 comprises conductive pads, conductive routing, and/or other conductive features that provide interconnections and electrical routing. In some embodiments, the substrate 410 may comprise an interposer, a semiconductor substrate (e.g., a wafer), a redistribution structure, an interconnect substrate, a core substrate, a printed circuit board (PCB), or the like. In some embodiments, the substrate 410 comprises active and/or passive devices. In other embodiments, the substrate 410 is free of active and/or passive devices.

In some embodiments, the conductive connectors 224 of the optical system 300 are placed on corresponding conductive pads (not separately illustrated) of the substrate 410 and then a reflow process is performed to bond the optical system 300 to the substrate 410. In this manner, the optical system 300 may be electrically connected to the substrate 410. In other embodiments, the optical system 300 may be bonded to the substrate 410 using dielectric-to-dielectric bonding and/or metal-to-metal bonding (e.g., direct bonding, fusion bonding, oxide-to-oxide bonding, hybrid bonding, or the like). In some embodiments, an underfill 412 may be deposited between the optical system 300 and the substrate 410.

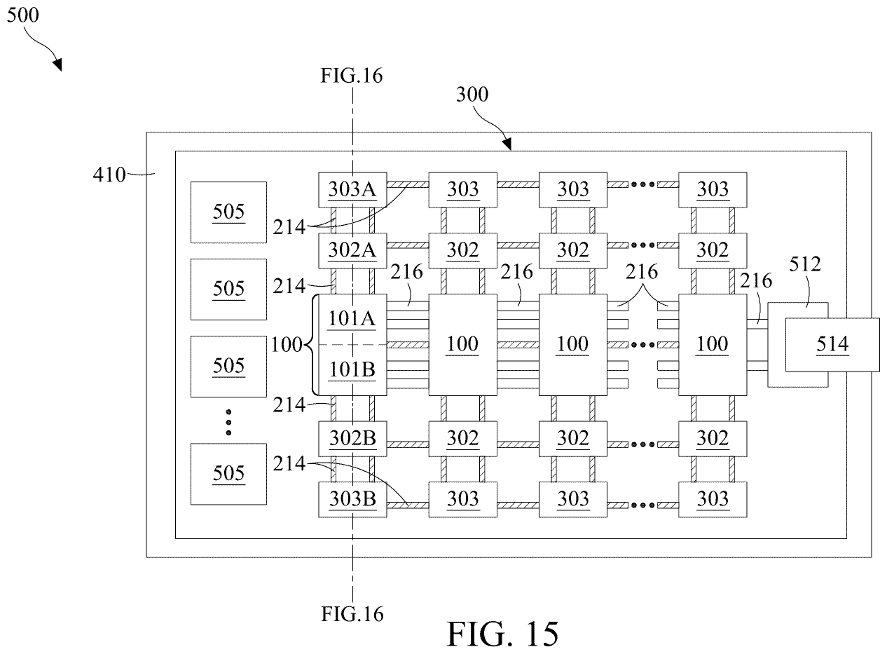

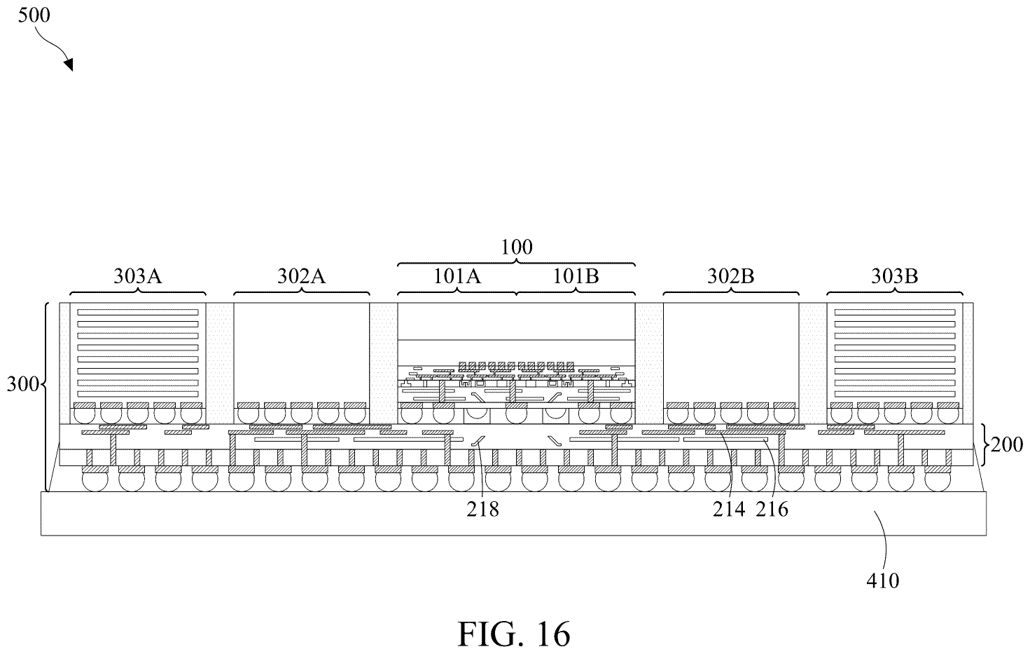

FIG. 15 illustrates a schematic plan view of a photonic structure 500 comprising an optical system 300 with optical packages 100, device dies 302, and a composite interposer 200, in accordance with some embodiments. The photonic structure 500 shown in FIG. 15 is intended as an illustrative example, and other structures having other configurations, arrangements, dimensions, or features are possible. The photonic structure 500 is similar to the photonic structure 400 of FIG. 14 except for the inclusion of some additional components such as laser dies 505, fiber coupler 512, and memory dies 303, which are described in greater detail below. For example, the photonic structure 500 includes an optical system 300 connected to a substrate 410, similar to the photonic structure 400. For clarity, some features are not shown in FIG. 15, such as some conductive features 214, some waveguides 216, or the like. For reference, FIG. 16 illustrates a cross-sectional view of the photonic structure 500 along the corresponding cross-section indicated in FIG. 15.

Referring to FIG. 15, the optical system 300 comprises multiple optical packages 100 and multiple device dies 302 that are connected to a composite interposer 200, similar to the optical system of FIG. 14. The optical system 300 of FIG. 15 also comprises memory dies 303 in addition to the device dies 302. In some embodiments, the device dies 302 are logic dies (e.g., xPU dies or the like) and the memory dies 303 are memory dies (e.g., HBM dies or the like). Other dies or combinations thereof are possible. In some embodiments, the optical packages 100, device dies 302, and memory dies 303 are electrically interconnected by conductive features 214 of the composite interposer 200. The conductive features 214 may enable relatively short-distance communications within the photonic structure 500 using electrical signals.

In some embodiments, an optical package 100 has two or more device regions 101 that each have associated device dies 302 and/or memory dies 303. As an example, the device region 101A is associated with and electrically connected to the device die 302A and the memory die 303A, and the device region 101B is associated with and electrically connected to the device die 302B and the memory die 303B. The other optical packages 100, device dies 302, and memory dies 303 in FIG. 15 may have similar associations, in some embodiments. However, the various optical packages 100, device dies 302, and memory dies 303 may be interconnected to each other in any suitable manner by the conductive features 214. Other associations, arrangements, or configurations are possible.

In some embodiments, waveguides 216 within the composite interposer 200 are utilized to transmit optical signals within the photonic structure 500, such as optical signals transmitted between optical packages 100. The optical signals may be transmitted between optical packages 100 and the waveguides 216, for example, using reflectors 76, lenses 90, and reflectors 218 as described previously. In this manner, the waveguides 216 may be used to provide relatively long-distance communications within the photonic structure 500 using optical signals. By using electrical signals over short distances and optical signals over long distances, the efficiency, speed, and/or bandwidth of the photonic structure 500 may be improved.

In some embodiments, the photonic structure 500 may comprise one or more laser dies 505 that provide optical power within the photonic structure 500. For example, the laser dies 505 may comprise laser diodes or the like that generate optical power. The laser dies 505 may be connected to the composite interposer 200 and may couple optical power into waveguides 216. In some embodiments, the optical power of the laser dies 505 is coupled into the waveguides 216 using reflectors and/or lenses (not illustrated), similar to that described for the optical packages 100. Other techniques for coupling optical power, such as the use of grating couplers or evanescent couplers, are possible. In other embodiments, laser dies 505 are not present.

In some embodiments, a fiber coupler 512 may be attached to the photonic structure 500 that facilitates communication between the photonic structure 500 and an optical fiber 514. The optical fiber 514 may comprise one or more optical fibers, which may be an array or the like. The fiber coupler 512 may be a fiber array unit (FAU) or the like that is configured to couple optical signals from the photonic structure 500 into the optical fiber 514 and/or couple optical signals from the optical fiber 514 into the photonic structure 500. For example, the fiber coupler 512 may be optically coupled to waveguides 216. In some embodiments, the fiber coupler 512 is coupled to the waveguides 216 using reflectors and/or lenses (not illustrated), similar to that described for the optical packages 100. Other techniques, such as the use of grating couplers or evanescent couplers, are possible. In some embodiments, the photonic structure 500 receives optical power provided by the optical fiber 514 through the fiber coupler 512. In other embodiments, the fiber coupler 512 is not present or multiple fiber couplers 512 may be used.

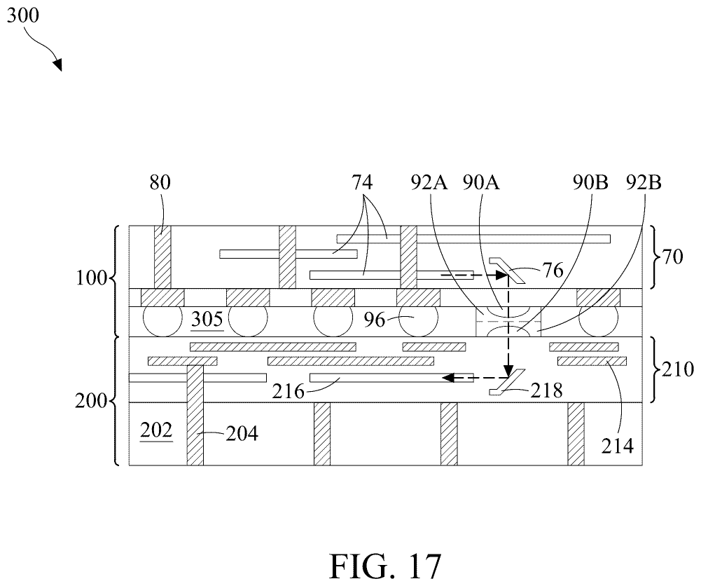

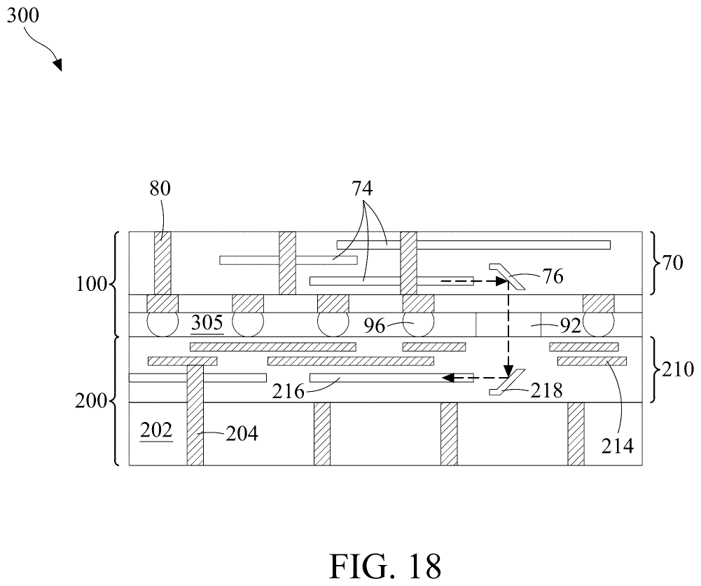

FIGS. 17 and 18 illustrate magnified portions of optical systems 300, in accordance with some embodiments. The magnified portions shown in FIGS. 17-18 are similar to that shown in FIG. 13, except that the embodiment of FIG. 17 includes two lenses 90A-B and the embodiment of FIG. 18 does not include a lens 90. It should be noted that any suitable embodiments described in the present disclosure may be configured with one lens (e.g., similar to FIG. 16), a pair of lenses (e.g., similar to FIG. 17), or no lenses (e.g., similar to FIG. 18), even if such a configuration is not separately illustrated.

Referring first to FIG. 17, an optical system 300 is shown in which a first lens 90A attached to the optical package 100 and a second lens 90B is attached to the composite interposer 200. The first lens 90A and the second lens 90B may be laser-written lenses similar to those described previously for the lens 90. A layer of optical glue 92A may be deposited on the lens 90A, and a layer of optical glue 92B may be deposited on the lens 90B. The layers of optical glue 92A-B may be deposited before connecting the optical package 100 to the composite interposer 200. In other embodiments, only one layer of optical glue 92 is deposited on one lens 90A or 90B, and the other lens 90A-B is covered by the optical glue 92 during connection of the optical package 100 to the composite interposer 200. In some cases, the use of a pair of lenses 90A-B rather than a single lens 90 can improve transmission efficiency or offset tolerance between the optical package 100 and the composite interposer 200.

Referring to FIG. 18, in some embodiments, a lens 90 is not present but a layer of optical glue 92 or the like is present between the optical package 100 and the composite interposer 200. In such embodiments, optical signals between the optical package 100 and the composite interposer 200 can be transmitted through the optical glue 92. In such embodiments, a layer of optical glue 92 may be deposited on the optical package 100 and/or on the composite interposer 200. In some cases, omitting the lens 90 may allow for a smaller distance (e.g., distance D1) between the optical package 100 and the composite interposer 200.

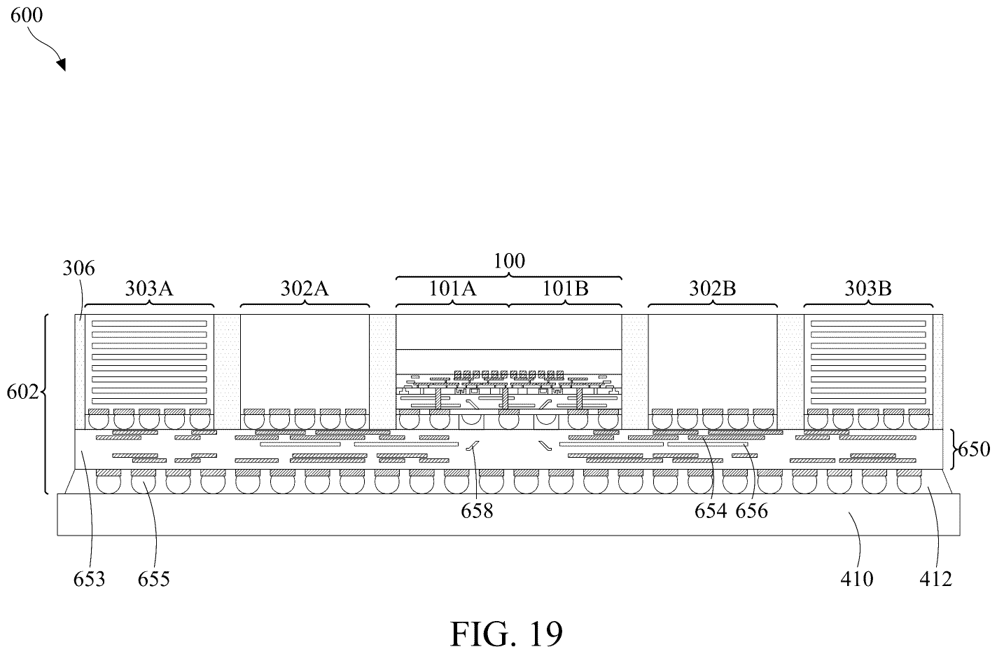

FIG. 19 illustrates a photonic structure 600, in accordance with some embodiments. The photonic structure 600 of FIG. 19 is similar to the photonic structure 500 of FIG. 16, except that the optical system 602 comprises a redistribution interposer 650 instead of a composite interposer 200. For example, the photonic structure 600 may comprise optical packages 100, device dies 302, memory dies 303, or the like, which are connected or otherwise attached to the redistribution interposer 650. The photonic structure 600 shown in FIG. 19 is an example, and other configurations are possible.

The redistribution interposer 650 may be, for example, an organic interposer, a redistribution structure, or the like. The redistribution interposer 650 may include a plurality of redistribution layers 654 formed in a plurality of dielectric layers 653 (not individually illustrated). The redistribution layers 654 may include conductive lines, conductive vias, conductive pads, or the like. The redistribution layers 654 may be formed of a conductive material, such as a metal, such as copper, cobalt, aluminum, gold, combinations thereof, or the like. In some embodiments, the dielectric layers 653 may comprise a polymer such as polybenzoxazole (PBO), polyimide, a benzocyclobuten (BCB) based polymer, or the like. In other embodiments, the dielectric layers 653 may comprise other suitable dielectric materials, such as silicon oxide or the like. The redistribution layers 654 may be formed using any suitable process, such as deposition, plating, damascene, dual damascene, or the like. In some embodiments, the redistribution interposer 650 is substantially free of active and passive devices.

In some embodiments, the redistribution interposer 650 also includes waveguides 656 and reflectors 658 formed in the dielectric layers 653. The waveguides 656 may be similar to the waveguides 216 described previously, and may be formed using similar techniques. For example, in some embodiments, the waveguides 656 may comprise silicon nitride. The reflectors 658 may be similar to the reflectors 218 described previously, and may be formed using similar techniques. For example, in some embodiments, the reflectors 658 may be formed by patterning dielectric layers 653 made of photosensitive material and then depositing metallic material. The dielectric layers 653 may be patterned using grayscale photolithography techniques, in some embodiments. Similar to the composite interposer 200, the reflectors 658 may facilitate the transmission of optical signals between the redistribution interposer 650 and an optical package 100. For example, optical signals may be transmitted through the lens 90 to the reflector 658 and into a corresponding waveguide 656.

In some embodiments, the redistribution interposer 650 may be formed on a carrier substrate (not illustrated). The optical packages 100, device dies 302, memory dies 303, or other components may be connected to the redistribution interposer 650 using techniques similar to those described for connecting components to the composite interposer 200. An encapsulant 306 may be formed over the components and the redistribution interposer 650. The carrier substrate may then be removed or etched to expose the redistribution interposer 650. Conductive connectors 655 may be formed on the redistribution interposer 650, which may be similar to the conductive connectors 224 described previously. The redistribution interposer 650 may be connected to a substrate 410 using the conductive connectors 655, and an underfill 412 may be deposited between the redistribution interposer 650 and the substrate 410. This is an example, and the redistribution interposer 650 and/or the photonic structure 600 may be formed using other process steps, materials, or techniques.

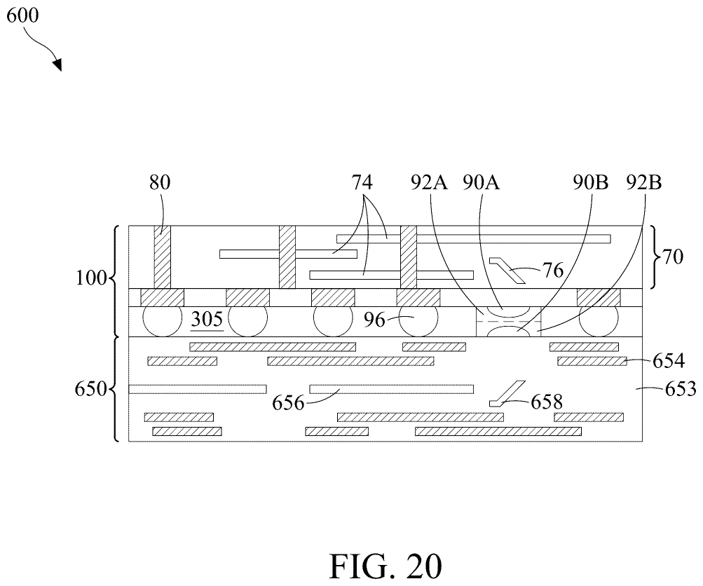

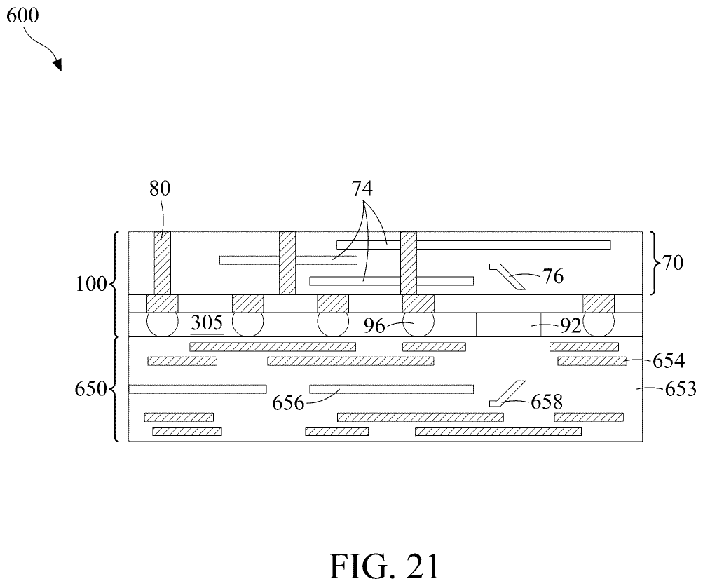

FIGS. 20 and 21 illustrate magnified portions of optical systems 600, in accordance with some embodiments. The magnified portions shown in FIGS. 20-21 are similar to that shown in FIG. 13, except that the embodiment of FIG. 20 includes two lenses 90A-B and the embodiment of FIG. 21 does not include a lens 90. Referring first to FIG. 20, an optical system 600 is shown in which a first lens 90A attached to the optical package 100 and a second lens 90B is attached to the redistribution interposer 650. The first lens 90A and the second lens 90B may be laser-written lenses similar to those described previously. A layer of optical glue 92A may be deposited on the lens 90A, and a layer of optical glue 92B may be deposited on the lens 90B. The layers of optical glue 92A-B may be deposited before connecting the optical package 100 to the redistribution interposer 650. In other embodiments, only one layer of optical glue 92 is deposited on one lens 90A or 92B, and the other lens 90A-B is covered by the optical glue 92 during connection of the optical package 100 to the redistribution interposer 650. In some cases, the use of a pair of lenses 90A-B rather than a single lens 90 can improve transmission efficiency or offset tolerance between the optical package 100 and the redistribution interposer 650.

Referring to FIG. 21, in some embodiments, a lens 90 is not present but a layer of optical glue 92 or the like is present between the optical package 100 and the redistribution interposer 650. In such embodiments, optical signals between the optical package 100 and the redistribution interposer 650 can be transmitted through the optical glue 92. In such embodiments, a layer of optical glue 92 may be deposited on the optical package 100 and/or on the redistribution interposer 650. In some cases, omitting the lens 90 may allow for a smaller distance between the optical package 100 and the redistribution interposer 650.

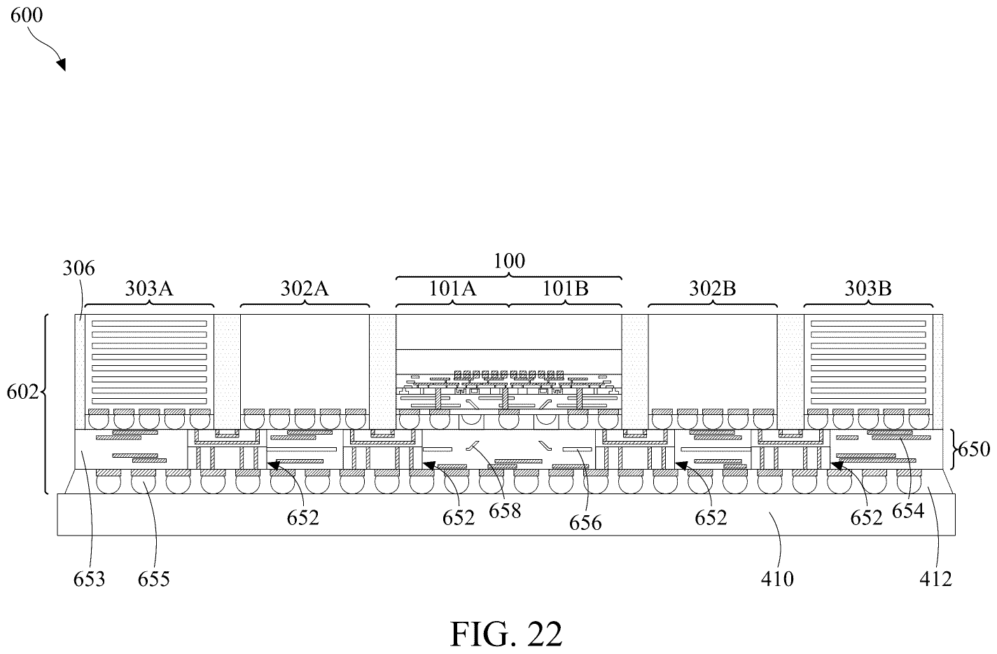

FIG. 22 illustrates a photonic structure 600, in accordance with some embodiments. The photonic structure 600 of FIG. 22 is similar to the photonic structure 600 of FIG. 19, except that local interconnects 652 are formed in the redistribution interposer 650 of the optical system 602. The local interconnects 652 may be, for example, chips, chiplets, local silicon interconnects, interconnect structures, or the like, that provide additional electrical interconnections within the redistribution interposer 650. For example, the local interconnects 652 may provide electrical connections between adjacent components, such as optical packages 100, device dies 302, and/or memory dies 303. The local interconnects 652 may include conductive features (e.g., conductive lines, vias, pads, or the like) formed in dielectric layers. The conductive features may be formed using suitable techniques, such as damascene, dual damascene, or the like. For example, in some cases, a local interconnect 652 may comprise an interconnect structure on a substrate, which may have through-substrate vias (TSVs) within, though other local interconnects 652 are possible. In some embodiments, the local interconnects 652 may be placed on a carrier substrate (not illustrated) and then the redistribution interposer 650 may be formed around the local interconnects 652. In some cases, the conductive features of the local interconnects 652 may have a smaller linewidth and/or pitch than the redistribution layers 654 of the redistribution interposer 650, which can allow for a greater density of electrical routing. The local interconnects 652 may or may not include passive devices or active devices. The local interconnects 652 shown in FIG. 22 are illustrative examples, and other local interconnects 652 or configurations thereof are possible.

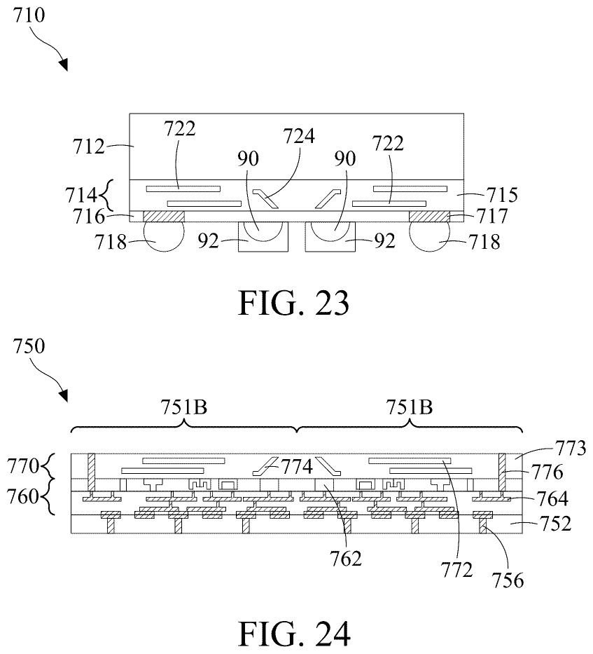

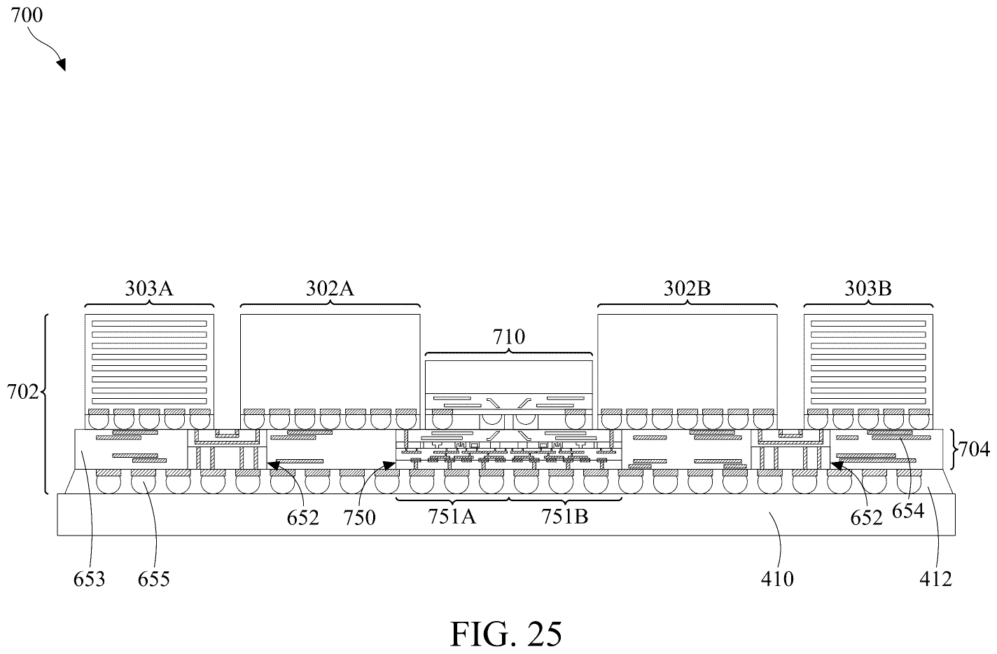

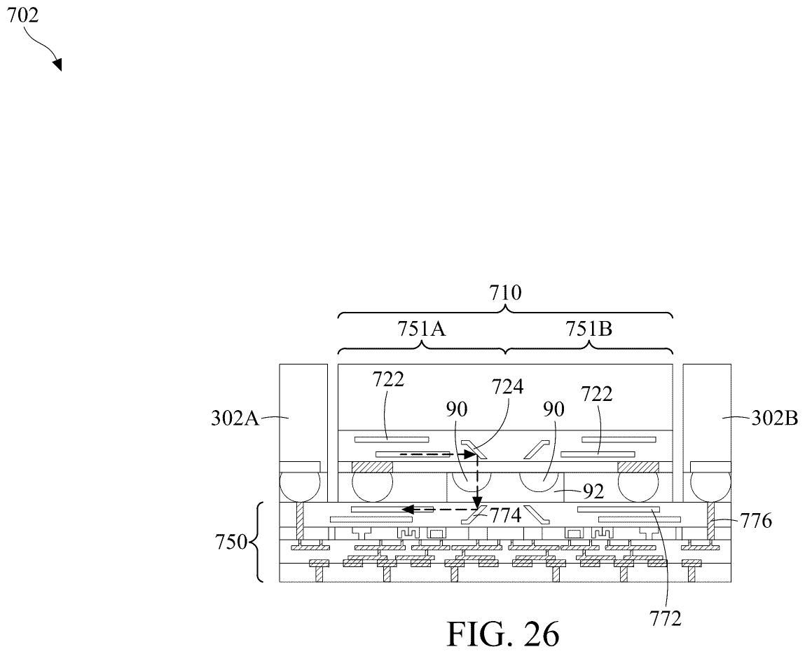

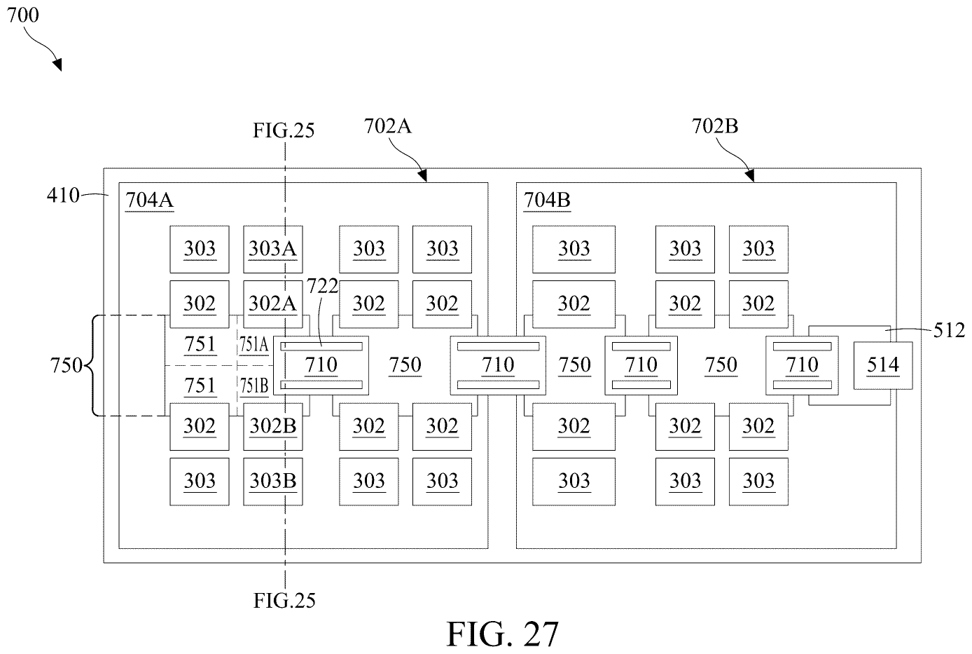

FIGS. 23, 24, 25, 26, and 27 illustrate intermediate steps in the formation of a photonic structure 700, in accordance with some embodiments. The photonic structure 700 is similar to the photonic structure 600 described for FIG. 22, except that the optical system 702 comprises one or more optical packages 750 within the redistribution interposer 704 and one or more bridge structures 710 attached to optical packages 750. In some embodiments, optical communication within the optical system 702 is not provided by waveguides formed in the redistribution interposer 704 but by waveguides 722 formed in bridge structures 710. Bridge structures 710 may also allow for optical communication between separate optical systems 702, described in greater detail below. FIG. 23 illustrates a cross-sectional view of a bridge structure 710, FIG. 24 illustrates a cross-sectional view of an optical package 750, FIG. 25 illustrates a cross-sectional view of a photonic structure 700, FIG. 26 illustrates a magnified view of an optical system 702, and FIG. 27 illustrates a schematic plan view of a photonic structure 700. Some features of the photonic structure 700 and/or process steps for the photonic structure 700 or components thereof are similar to those described previously, and as such some previously described details may not be repeated.

FIG. 23 illustrates a bridge structure 710, in accordance with some embodiments. The bridge structure 710 is used to provide transmission of optical signals between components of the photonic structure 700. In some embodiments, the bridge structure 710 comprises an optical interconnect structure 714 formed on a substrate 712. The optical interconnect structure 714 may be similar to the optical interconnect structure 70 of the optical package 100, and may be formed using similar materials and/or techniques. For example, the substrate 712 may be similar to the first substrate 10 of the optical package 100 (see FIG. 1) and may be, e.g., a silicon substrate, though other substrates are possible. The optical interconnect structure 714 may comprise waveguides 722 and reflectors 724 formed in dielectric layers 715. The waveguides 722 and reflectors 724 may be similar to the photonic components 74 and reflectors 76 of the optical interconnect structure 70 (see FIG. 6) and may be formed using similar techniques. The dielectric layers 715 may be similar to the dielectric layers 72. For example, in some embodiments, the dielectric layers 715 may be silicon oxide layers, but other materials are possible. The reflectors 724 are configured to receive light from waveguides 722 and redirect it vertically and/or receive light and redirect it into waveguides 722, similar to the photonic components 74 and reflectors 76 of the optical interconnect structure 70.

In some embodiments, a passivation layer 716 may be formed on the optical interconnect structure 714, and UBMs 717 may be formed in the passivation layer 716. The passivation layer 716 and the UBMs 717 may be similar to the passivation layer 82 and UBMs 717 of the optical package 100. Conductive connectors 718 may be formed on the UBMs 717, which may be similar to the conductive connectors 96 of the optical package 100. In some cases, the bridge structures 710 are free of electrical routing, and the conductive connectors 718 are used to make physical attachment to an underlying component (e.g., an optical package 750). One or more lenses 90 may be attached to the bridge structure 710, with each lens 90 configured to transmit light to a reflector 724 or received from a reflector 724. The lenses 90 may be laser-written lenses, in some embodiments. This is an example, and other bridge structures 710 are possible.

FIG. 24 illustrates an optical package 750, in accordance with some embodiments. The optical package 750 comprises an optical interposer 760 formed on an optical interconnect structure 770, in some embodiments. The optical package 750 also comprises an electronic die 752 bonded to the optical interposer 760, in some embodiments. The optical interposer 760 may be similar to the optical interposer 50 (see FIG. 3), and may be formed using similar techniques. For example, the optical interposer 760 may comprise photonic components 762 and conductive features 764, which may be similar to the photonic components 18 and conductive features 24 described previously for FIG. 3. The electronic die 752 may be similar to the electronic die 60 described previously for FIG. 4. For example, the electronic die 752 may be bonded (e.g., using dielectric-to-dielectric bonding and/or metal-to-metal bonding) to the optical interposer 760, and the electronic die 752 may be electrically connected to photonic components 762 through the conductive features 764. In some embodiments, the electronic die 752 may comprise through-substrate vias 756, which may be electrically connected to the optical interposer 760, in some cases.

In some embodiments, the optical interconnect structure 770 of the optical package 750 may be similar to the optical interconnect structure 70 (see FIG. 6), and may be formed using similar materials or techniques. For example, the optical interconnect structure 770 may comprise waveguides 772 and reflectors 774 formed in dielectric layers 773. The waveguides 772 and reflectors 774 may be similar to the photonic components 74 and reflectors 76 of the optical interconnect structure 70 and may be formed using similar techniques. The dielectric layers 773 may be similar to the dielectric layers 72. For example, in some embodiments, the dielectric layers 773 may be silicon oxide layers, but other materials are possible. In some embodiments, one or more waveguides 772 may be optically coupled to a photonic component 762. The reflectors 774 are configured to receive light from waveguides 772 and redirect it vertically and/or receive light and redirect it into waveguides 772, similar to the photonic components 74 and reflectors 76 of the optical interconnect structure 70. In some embodiments, the optical package 750 also includes through vias 776 extending through the optical interconnect structure 770 to connect to conductive features 764 of the optical interposer 760.

In some embodiments, the optical package 750 may comprise multiple device regions 751 (e.g., device regions 751A-B). The device regions 751 may be similar to the device regions 101 described previously for the optical package 100. For example, each device region 751 may be a region of the optical package 750 that is at least partially dedicated to processing particular optical signals. In this manner, the optical package 750 may provide optical signal processing and functionality similar to that described previously for the optical package 100.

FIG. 25 illustrates a photonic structure 700, in accordance with some embodiments. As mentioned above, the photonic structure 700 is similar to the photonic structure 600 described for FIG. 22, except that the redistribution interposer 704 comprises an optical package 750 and a bridge structure 710 is attached to the optical package 750. The redistribution interposer 704 may be similar to the redistribution interposer 650 described previously for FIG. 22. For example, the redistribution interposer 704 may comprise a plurality of redistribution layers 654 formed in a plurality of dielectric layers 653. Local interconnects 652 may be within the redistribution interposer 704, which may be similar to the local interconnects 652 described previously for FIG. 22. For example, the local interconnects 652 may electrically connect device dies 302, memory dies 303, and/or conductive connectors 655. In some embodiments, the redistribution interposer 704 is free of waveguides and/or other photonic components.

One or more optical packages 750 are formed within the redistribution interposer 704. For example, in some embodiments, the optical packages 750 (and/or local interconnects 652) may be placed on a carrier substrate, and the redistribution interposer 704 is then formed around them. In other embodiments, the redistribution interposer 704 may be formed first, openings may then be formed in the redistribution interposer 704, and then the optical packages 750 (and/or local interconnects 652) may be placed in the openings. In some embodiments, the optical packages 750 are electrically connected to conductive connectors 655. In some embodiments, top surfaces and/or bottom surfaces of the redistribution interposer 704 and the optical packages 750 may be level or coplanar.

After forming the redistribution interposer 704, the local interconnect structures 652, and the optical packages 750, the device dies 302, memory dies 303, and/or bridge structure 710 may be attached. The device dies 302, memory dies 303, and bridge structures 710 may be attached using their respective conductive connectors, as described previously. For example, the device dies 302, memory dies 303, and bridge structures 710 may be placed and then a reflow process may be performed. In some embodiments, an optical package 750 may comprise bonding pads (not illustrated) to facilitate bonding with conductive connectors. In some embodiments, the device dies 302 and memory dies 303 may be electrically connected to the redistribution interposer 704, local interconnect structures 652, and/or optical packages 750.

FIG. 26 illustrates a magnified portion of an optical system 702, in accordance with some embodiments. For clarity, not all features have been labeled. Similar to other embodiments herein, the use of reflectors 724/774 and/or lenses 90 can facilitate efficient transmission of light between the optical package 750 and the bridge structure 710. For example, a reflector 724 in the bridge structure 710 may be configured to receive light from a waveguide 722 and redirect the received light through the lens 90, as indicated by the dashed arrows in FIG. 26. A corresponding reflector 774 in the optical package 750 may be configured to receive light from the lens 90 and redirect the light into a waveguide 772. Similarly, the reflector 774 may receive light from the waveguide 772 and redirect the light through the lens 90 and into the reflector 724, which redirects the light into the waveguide 722. In this manner, optical communication and optical processing may be performed by the optical package(s) 750 and bridge structure(s) 710 of the photonic structure 700.

As shown in FIG. 26, an optical glue 92 may cover more than one lens 90, in some embodiments. In other embodiments, pairs of lenses (see FIG. 17) may be formed or no lenses (see FIG. 18) may be present. Additionally, in some embodiments, a through via 776 may be electrically connected to a component such as a device die 302, a memory die 303, or the like. This is an example, and other configurations or arrangements are possible.

FIG. 27 illustrates a schematic plan view of a photonic structure 700 comprising multiple optical system 702A-B, in accordance with some embodiments. The photonic structure 700 shown in FIG. 27 is intended as an illustrative example, and other structures having other configurations, arrangements, dimensions, or features are possible. For example, a photonic structure 700 may comprise another number of optical packages 750, bridge structures 710, or other components, which may have a different arrangement than shown. For clarity, some features are not shown in FIG. 27, such as some conductive features, some waveguides, or the like. For reference, FIG. 25 illustrates a cross-sectional view of a photonic structure 700 along a corresponding cross-section indicated in FIG. 27.

The optical systems 702A-B of the photonic structure 700 may be similar to the optical system 750 described for FIG. 25. For example, the optical systems 702A-B each comprise a corresponding redistribution interposer 704A-B. The redistribution interposers 704A-B of each optical system 702A-B are connected to the package substrate 410, similar to the optical system 702 shown in FIG. 25. Optical packages 750 and/or local interconnects 652 (not illustrated in FIG. 27) are formed within the redistribution interposers 704A-B. Device dies 302 and memory dies 303 are connected to the redistribution interposers 704A-B, and may be electrically interconnected by redistribution layers 654 (not illustrated) within the redistribution interposers 704A-B and/or by local interconnects 652 within the redistribution interposers 704A-B. In some embodiments, laser dies (not illustrated), a fiber coupler 512, or other components may be attached to one or more redistribution interposers 704A-B.

The photonic structure 700 includes multiple bridge structures 710, in accordance with some embodiments. The bridge structures 710 may each be attached to multiple optical packages 750, which may include multiple optical packages 750 of the same optical system 702A or 702B and/or multiple optical packages 750 of different optical systems 702A and 702B. The waveguides 722 of the bridge structures 710 may be optically coupled to underlying optical packages 750 using reflectors 724/774 and/or lenses 90, as described previously for FIG. 26. In some embodiments, optical signals may be transmitted between optical packages 750 by the waveguides 722 of the bridge structures 710. In some embodiments, optical signals may be communicated between the optical packages 750 of different optical systems 702 by a bridge structure 710. In some embodiments, a bridge structure 710 may be used to transmit optical signals between a fiber coupler 512 and an optical package 750. In some embodiments, a bridge structure 710 may be used to transmit optical power from a laser die (not illustrated) to an optical package 750. A bridge structure 710 may overlap one or more optical packages 750, as shown in FIG. 27. In some cases, using bridge structures 710 to transmit optical signals (e.g., instead of waveguides in a redistribution interposer 704) can allow for more efficient transmission of optical signals, improved waveguide fabrication, reduced optical loss, and reduced structure dimensions. In this manner, the use of optical packages 750 and bridge structures 710 as described herein may provide relatively long-distance communications within the photonic structure 700 using optical signals. By using electrical signals over short distances and optical signals over long distances, the efficiency, speed, and/or bandwidth of the photonic structure 700 may be improved.

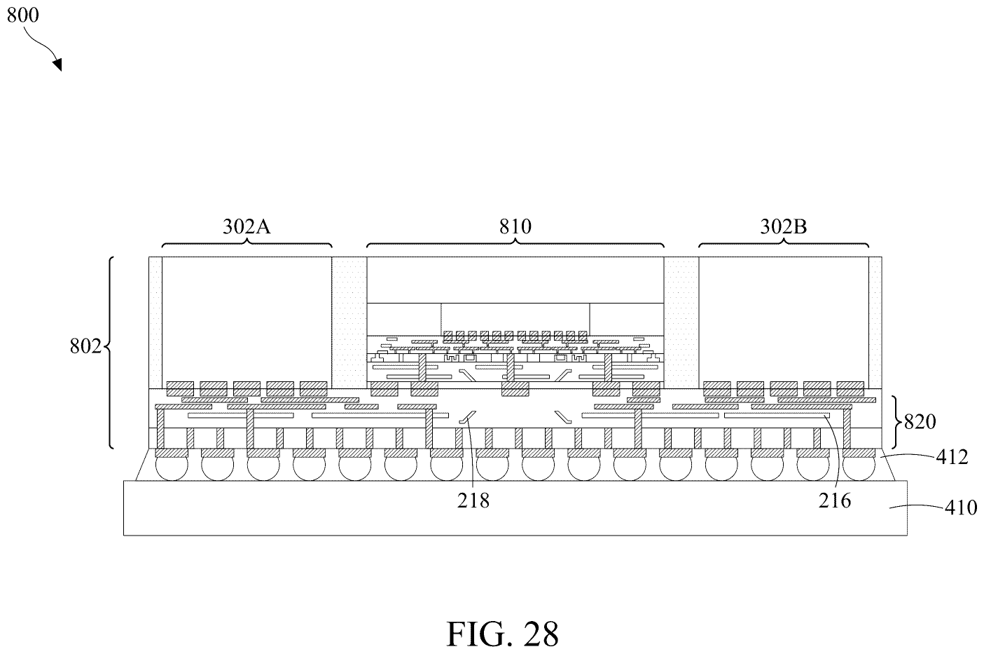

FIG. 28 illustrates a photonic structure 800, in accordance with some embodiments. The photonic structure 800 is similar to the photonic structure 400 described for FIG. 14, except that direct bonding (e.g., fusion bonding, dielectric-to-dielectric bonding, metal-to-metal bonding, or the like) is used to connect components rather than using conductive connectors. For example, the photonic structure 800 comprises a composite interposer 820 that is similar to the composite interposer 200 described previously. For example, the composite interposer 820 comprises conductive features 214, waveguides 216, and/or reflectors 218 formed in a plurality of dielectric layers 212. The composite interposer 820 may also comprise bonding pads (not separately labeled) formed in the top-most dielectric layer 212, which may also be considered a bonding layer. The optical package 810 may be similar to the optical package 100 described for FIG. 7. For example, the optical package 810 may comprise photonic components 74 (e.g., waveguides) and reflectors 76 formed in a plurality of dielectric layers 72. The optical package 810 may also comprise bonding pads (not separately labeled) formed in the bottom-most dielectric layer 72, which may also be considered a bonding layer.

In the photonic structure 800, conductive connectors are not formed on the optical package 810, and lenses are not attached to the optical package 810. The optical package 810 is directly bonded to the composite interposer 820 using dielectric-to-dielectric bonding and/or metal-to-metal bonding. For example, the bonding layer 72 of the optical package 810 may be bonded to the bonding layer 212 of the composite interposer 820 using dielectric-to-dielectric bonding, and bonding pads of the optical package 810 may be bonded to the bonding pads of the composite interposer 820 using metal-to-metal bonding. The direct bonding process may be similar to the bonding process described previously for FIG. 4. In some embodiments, other components such as device dies 302 or the like may also be directly bonded to the composite interposer 820. Direct bonding of components such as that described for the photonic structure 800 may be utilized in any suitable embodiments described herein.

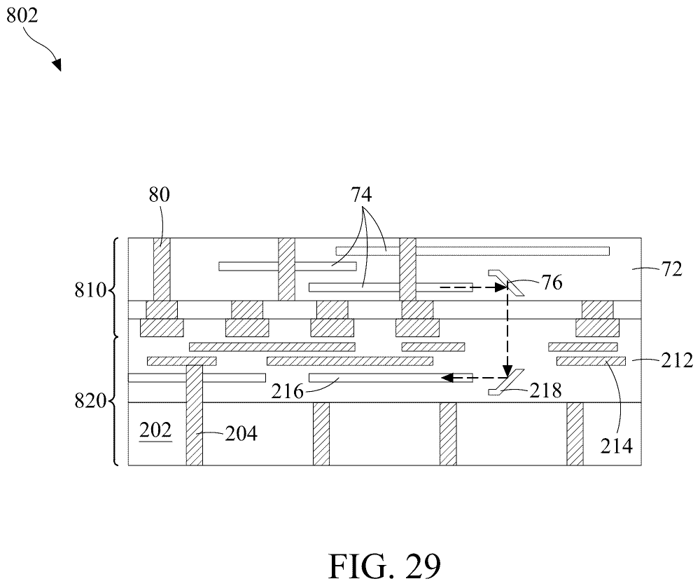

FIG. 29 illustrates a magnified view of a portion of an optical system 802, in accordance with some embodiments. The optical system 802 of FIG. 29 may be similar to the optical system 802 of FIG. 28. In some embodiments, a reflector 76 may be configured to receive light from a photonic component 74 and reflect the received light vertically through the dielectric layers 72 and into the dielectric layers 212, as indicated by the dashed arrows in FIG. 29. The reflector 218 may be configured to receive the light and couple it into a waveguide 216. Similarly, the reflector 218 may be configured to receive light from a waveguide 216, redirect it vertically through the dielectric layers 212 and into the dielectric layers 72, where the light is coupled into a photonic component 74 by a reflector 76. In some cases, directly bonding the optical package 810 to the composite interposer 820 may improve transmission efficiency, reduce signal loss, and reduce structure size.

Embodiments of the present disclosure have some advantageous features. Forming reflectors with corresponding waveguides in optical structures can allow light from the waveguides to be transmitted vertically between the optical structures. Further, the reflectors may be configured to receive vertically transmitted light and couple it into a corresponding waveguide of the same optical structure. Combining waveguides and corresponding reflectors in this manner can allow for efficient transmission of optical signals between overlying optical structures. Additionally, lenses may be formed between the optical structures that reshapes or focuses the light between the corresponding reflectors, improving transmission efficiency and increasing offset tolerance. Using laser-writing techniques to form the lenses may allow for more efficient and smaller lens design. In some cases, laser-written lenses may allow for larger vertical distances between the overlying optical structures, and may be small enough to allow the optical structures to be connected using solder bumps or the like with reduced optical loss. For example, a laser-written lens may allow optical signals to be vertically transmitted across vertical distances of about 30 μm or more, in some cases. The reflectors and/or lenses may be used to couple optical signals into waveguides that efficiently transmit optical signals over long distances. By using electrical signals over short distances and optical signals over long distances, the efficiency, speed, and/or bandwidth of a device, package, or structure may be improved.

In an embodiment of the present disclosure, a package includes an interposer, the interposer including a first waveguide and a first reflector that is optically coupled to the first waveguide; and an optical package attached to the interposer, wherein the optical package includes a second waveguide; and a second reflector that is optically coupled to the second waveguide, wherein the second reflector is vertically aligned with the first reflector. In an embodiment, the package includes a first lens between the interposer and the optical package, wherein the first lens, the first reflector, and the second reflector are vertically aligned. In an embodiment, the first lens is attached to the optical package, and the package includes a second lens between the interposer and the optical package, wherein the second lens and the first lens are vertically aligned. In an embodiment, first lens includes a laser-written material. In an embodiment, the optical package is attached to the interposer by solder bumps. In an embodiment, the optical package includes a photonic component and an electronic die, wherein the photonic component is optically coupled to the first waveguide and electrically coupled to the electronic die. In an embodiment, the package includes a logic die connected to the interposer. In an embodiment, the first waveguide and the second waveguide include silicon nitride.

In an embodiment of the present disclosure, a package includes a first optical structure that includes an electronic die, conductive lines, photonic components, first waveguides, and first reflective structures; and a second optical structure bonded to the first optical structure, wherein the second optical structure includes second waveguides and second reflective structures, wherein individual first reflective structures respectively correspond to individual second reflective structures. In an embodiment, the first reflective structures include a metallic layer. In an embodiment, the second optical structure is free of conductive lines. In an embodiment, the first optical structure is laterally surrounded by a redistribution structure. In an embodiment, the package includes local interconnect structures within the redistribution structure. In an embodiment, the package includes a third optical structure that includes third waveguides and third reflective structures, wherein the second optical structure is bonded to the third optical structure, wherein individual third reflective structures respectively correspond to individual second reflective structures. In an embodiment, the second optical structure overlaps the first optical structure and the third optical structure. In an embodiment, the package includes lenses attached to the second optical structure, wherein the lenses are between the first optical structure and the second optical structure.

In an embodiment of the present disclosure, a method includes forming an optical interposer comprising an interconnect structure over a photonic component, wherein the interconnect structure is electrically coupled to the photonic component; bonding an electronic die to a top side of the optical interposer, wherein the electronic die is electrically coupled to the interconnect structure; forming an optical interconnect structure on a bottom side of the optical interposer, wherein the optical interconnect structure includes a first waveguide and a first reflector, wherein the first reflector is optically coupled to the first waveguide; performing a laser-writing process to form a lens; attaching the lens to a bottom side of the optical interconnect structure, wherein the lens is optically coupled to the first reflector; and forming conductive connectors on the bottom side of the optical interconnect structure. In an embodiment, the method includes attaching the conductive connectors to an interposer, wherein the interposer includes a second waveguide and a second reflector, wherein the second reflector is optically coupled to the lens after attaching the conductive connectors. In an embodiment, the method includes performing a grayscale photolithography process to form the first reflector. In an embodiment, attaching the lens includes depositing an optical glue on the bottom side of the optical interconnect structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first waveguide in a first dielectric layer;
forming a first interconnect structure over a top side of the first dielectric layer;
attaching an electronic die to the first interconnect structure;
forming a second interconnect structure over a bottom side of the first dielectric layer, wherein the second interconnect structure comprises a second waveguide that is optically coupled to the first waveguide;
bonding a lens structure to the second interconnect structure, wherein the lens structure is optically coupled to the second waveguide; and
attaching an interposer to the second interconnect structure, wherein the interposer comprises a third waveguide, wherein the lens structure is between the second interconnect structure and the interposer, wherein the third waveguide is optically coupled to the lens structure.

2. The method of claim 1, wherein the second interconnect structure further comprises a reflector that is optically coupled to the second waveguide.

3. The method of claim 2 further comprising forming the reflector in the second interconnect structure using grayscale photolithography.

4. The method of claim 1, wherein the first waveguide and the second waveguide are different materials.

5. The method of claim 1, wherein the lens structure comprises an optical glue.

6. The method of claim 1, wherein the lens structure comprises two lenses.

7. The method of claim 1 further comprising performing a laser writing process to form the lens structure.

8. The method of claim 1 further comprising forming a photonic component in the first dielectric layer, wherein the photonic component is optically coupled to the first waveguide and electrically coupled to the first interconnect structure.

9. A method comprising:
forming a redistribution structure, comprising:
forming a plurality of redistribution layers in a plurality of first dielectric layers;
forming a first waveguide and a second waveguide in the plurality of first dielectric layers; and
forming a first reflector and a second reflector in the plurality of first dielectric layers, wherein the first reflector is optically coupled to the first waveguide and the second reflector is optically coupled to the second waveguide;
forming an optical package, comprising:
forming a third reflector and a fourth reflector in a plurality of second dielectric layers;
forming an interconnect structure over the plurality of second dielectric layers; and
attaching an electronic die to the interconnect structure;
attaching a first lens and a second lens to the optical package; and
attaching the optical package to the redistribution structure, wherein the first lens is optically coupled to the first reflector and the third reflector, wherein the second lens is optically coupled to the second reflector and the fourth reflector.

10. The method of claim 9 further comprising attaching a semiconductor die to the redistribution structure adjacent the optical package.

11. The method of claim 9, wherein the electronic die comprises first device region corresponding to the first waveguide and a second device region corresponding to the second region.

12. The method of claim 9, wherein the redistribution structure is formed on a semiconductor substrate comprising through vias.

13. The method of claim 9 further comprising forming a third waveguide and a fourth waveguide over the plurality of second dielectric layers, wherein the third waveguide is optically coupled to the third reflector and the fourth waveguide is optically coupled to the fourth reflector.

14. The method of claim 9, wherein attaching the optical package to the redistribution structure comprises attaching conductive connectors of the optical package to the redistribution structure.

15. The method of claim 14 further comprising depositing an underfill around the conductive connectors, the first lens, and the second lens.

16. A package comprising:
an interposer comprising a plurality of optical packages, wherein each optical package comprises a lower waveguide and a lower reflector; and
an optical bridge structure overlapping at least two optical packages of the plurality of optical packages, wherein the optical bridge structure comprises a plurality of upper waveguides and a plurality of upper reflectors, wherein each upper reflector of the optical bridge structure is optically coupled to a corresponding lower reflector of the at least two optical packages.

17. The package of claim 16, wherein at least one upper waveguide overlaps the at least two optical packages.

18. The package of claim 16 further comprising a plurality of lenses between the interposer and the optical bridge structure, wherein each upper reflector of the optical bridge structure is optically coupled to a corresponding lower reflector of the at least two optical packages through a corresponding lens.

19. The package of claim 16, wherein at least two upper reflectors are optically coupled to the same upper waveguide.

20. The package of claim 16, wherein the interposer further comprises a redistribution structure that surrounds each optical package of the plurality of optical packages.
